(19) United States
(12) Patent Application Publication
(10) Pub. No.: US 2026/0090444 A1
(43) Pub. Date: Mar. 26, 2026

(54) LOCAL SILICON INTERPOSER DIE WITH METALLIC VIAS, HAVING A BARRIER STRUCTURE AND METHODS OF FORMING THE SAME

(71) Applicant: Taiwan Semiconductor Manufacturing Company Limited, Hsinchu (TW)

(72) Inventors: Yu-Sheng Wang, Hsinchu City (TW); Cheng-Shiuan Wu, Hsinchu (TW); Kai-Cheng Chen, Taoyuan City (TW); Wen-Yi Lin, New Taipei City (TW); Zhihua Zou, Hsinchu (TW)

(21) Appl. No.: 18/894,569

(22) Filed: Sep. 24, 2024

(51) Int. Cl. H01L 23/00

(52) U.S. Cl. CPC H10W 72/90; H10W 72/019; H10W 72/01931; H10W 72/01953; H10W 72/923; H10W 72/934; H10W 72/942; H10W 72/952; H10W 72/953

(57) ABSTRACT

Barrier or cladding structures that prevent top vias from chemically reacting to tape residue or other impurities address reliability issues in local silicon interposer interconnection in semiconductor packaging by mitigating metal atom migration and wire growth, thereby enhancing long-term reliability. The via cladding structure incorporates a multi-layered barrier comprising, alone or in any combination, SiOCH, SiOₓ, SiON, SiNₓ, CuOₓ, Ta, Ti, TaN, TiN, Mo, MoN, TaC, TiC, TaCN, or TiCN, enhancing electrical performance and long-term reliability. The method of forming the cladding or barrier structure involves a combination of cladding layer deposition, patterning, wet etch, isotropic dry etch or anisotropic dry etch process, flowable dielectric deposition or spin-coat dielectric, and chemical mechanical planarization (CMP) to ensure robust and reliable connections. The integration of these layers mitigates issues related to metal atom migration and wire growth, providing a solution for the growing demand for high-density, high-performance semiconductor packages.

### BACKGROUND

In semiconductor packaging technology, there is a growing demand for multiple levels of connections between processors and memories to achieve a wide signal bandwidth and reduced signal delay. Various connection schemes may include Cu-to-Cu, Cu-to-Bump, Cu-to-micro bump with underfill, or oxide-to-oxide bonding. However, the direct exposure of copper vias (as copper is one of the more common via materials) to grinding tape presents reliability concerns due to copper migration, copper wire growth, and copper loss. The copper migration, copper wire growth, and copper loss, alone or in any combination, may lead to performance degradation, electrical failures, and compromised long-term reliability of the packaged device. Copper atoms may migrate along the via interface or grinding tape residue, accumulating at specific locations and forming copper wires, which may cause potential short circuits or altered electrical characteristics.

Moreover, connecting copper vias between the redistribution layer (RDL) in a local silicon interposer and the RDL in the semiconductor package poses additional challenges. The transition from one substrate to another introduces additional challenges, such as differences in coefficients of thermal expansion (CTE) and stress distribution, exacerbating the risk of via-related failures. Electromigration, driven by the movement of copper atoms under current flow, may lead to Cu wire growth, voids, or cracks, resulting in circuit failure and affecting long-term reliability. Existing solutions, such as using post-clean processes or polymer protective layers, often leave residues or cause additional thermal mismatches and stress, exacerbating reliability concerns. Addressing these issues is beneficial to ensure the robustness and longevity of semiconductor packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A shows a top view of the intermediate exemplary local silicon interposer die with via structures designed to connect with another LSI die or other packages.

FIG. 1B illustrates a vertical cross-sectional view of the intermediate exemplary local silicon interposer die along the A-A′ line of FIG. 1A, which may be used during the fabrication of the interconnection of the packages as described in the present disclosure.

FIG. 2 is a series of schematic vertical cross-sectional views depicting the sequence of process steps to form various embodiment intermediate cladding structures of different types that may ultimately lead to the desired structures according to an aspect of the present disclosure.

FIG. 3 is a series of schematic vertical cross-sectional views depicting subsequent process steps to form various embodiment cladding structures, which may include flowable oxide or spin-on dielectric consistent with various embodiment structures of the present disclosure.

FIG. 4 is a series of schematic vertical cross-sectional views depicting subsequent process steps to form various embodiment cladding structures, which may include flowable oxide or spin-on dielectric by partial etch back consistent with various embodiment structures according to an aspect of the present disclosure.

FIG. 5 is a series of schematic vertical cross-sectional views depicting subsequent process steps to form various embodiment cladding structures.

FIG. 6A is an exemplary top view of a local silicon interposer after the completion of various dielectric depositions on the surface of the top vias and the local silicon interposer.

FIG. 6B shows a vertical cross-sectional view of the vias and redistribution layers of a local silicon interposer along the A-A′ line in FIG. 6A after the completion of various dielectric depositions on the surface of the top vias and the local silicon interposer.

FIG. 7A is an exemplary top view of a local silicon interposer after the complete attachment of a grinding tape on the surface of continuous cladding layers formed through multiple steps of depositions.

FIG. 7B is an exemplary vertical cross-sectional view of a local silicon interposer along A-A′ line in FIG. 7A after the complete attachment of a grinding tape on the surface of continuous cladding layers formed through multiple steps of depositions.

FIG. 8A is an exemplary top view of a local silicon interposer after stripping a grinding tape from the surface of continuous cladding layers formed through multiple steps of depositions.

FIG. 8B is an exemplary vertical cross-sectional view of a local silicon interposer along A-A's line in FIG. 8A after stripping a grinding tape from the surface of continuous cladding layers formed through multiple steps of depositions.

FIG. 9A is an exemplary top view of a local silicon interposer after a complete deposition of flowable oxide or dielectric on the surface of continuous cladding layers formed through multiple steps of cladding layer depositions.

FIG. 9B is an exemplary vertical cross-sectional view of a local silicon interposer along A-A′ line in FIG. 9A after a complete deposition of flowable oxide or spin-on dielectric on the surface of continuous cladding layers formed through multiple steps of cladding layer depositions.

FIG. 10A is an exemplary top view of the cladding structure on the local silicon interposer after the chemical mechanical polishing (CMP) of flowable oxide or spin-on dielectric, stopping on the top surface of top vias.

FIG. 10B is an exemplary vertical cross-sectional view of the cladding structure on the local silicon interposer in A-A′ line in FIG. 10A after the chemical mechanical polishing (CMP) of flowable oxide or spin-on dielectric, stopping on the top surface of top vias.

FIG. 11A is an exemplary top view of the cladding structure on the local silicon interposer after partial etch back of flowable oxide or spin-on dielectric shown in FIGS. 10A and 10B.

FIG. 11B is an exemplary vertical cross-sectional view of the cladding structure on the local silicon interposer along A-A′ line in FIG. 11A after partial etch back of flowable oxide or spin-on dielectric shown in FIGS. 10A and 10B.

FIG. 12A is an exemplary top view of cladding structure on the local silicon interposer after the complete etch back of flowable oxide or spin-on dielectric shown in FIGS. 10A and 10B.

FIG. 12B is an exemplary vertical cross-sectional view of the cladding structure on the local silicon interposer along A-A′ line in FIG. 12A after the complete etch back of flowable oxide or spin-on dielectric shown in FIGS. 10A and 10B.

FIG. 13A is an exemplary top view of a local silicon interposer after the completion of spacer formation around top vias following an anisotropic etch of various dielectric layers on the surface of the top vias and the local silicon interposer.

FIG. 13B shows an exemplary vertical cross-sectional view of top vias along A-A′ line in FIG. 13A and a local silicon interposer after the completion of spacer formation around top vias following an anisotropic etch of various dielectric layers on the surface of top vias and the local silicon interposer.

FIG. 14A is an exemplary top view of a local silicon interposer after the complete attachment of a grinding tape on the surface of the top vias, spacer claddings, and the local silicon interposer.

FIG. 14B is an exemplary cross-sectional view of a local silicon interposer along A-A′ line in FIG. 14A after the complete attachment of a grinding tape on the surface of the top vias, spacer claddings, and the local silicon interposer.

FIG. 15A is an exemplary top view of a local silicon interposer after stripping a grinding tape from the surface of the top vias, spacer claddings, and the local silicon interposers.

FIG. 15B is an exemplary vertical cross-sectional view of a local silicon interposer along A-A′ line in FIG. 15A after stripping a grinding tape from the surface of the top vias, spacer claddings, and the local silicon interposer.

FIG. 16A is an exemplary top view of a local silicon interposer after a complete deposition of flowable oxide or spin-on dielectric on spacer claddings, top vias, and the surface of the local silicon interposer.

FIG. 16B is an exemplary cross-sectional view of a local silicon interposer along A-A′ line in FIG. 16A after a complete deposition of flowable oxide or spin-on dielectric on spacer claddings, top vias, and the surface of the local silicon interposer.

FIG. 17A is an exemplary top view of the cladding structure on the local silicon interposer after the chemical mechanical polishing (CMP) of flowable oxide or spin-on dielectric, stopping on top vias and spacer claddings.

FIG. 17B is an exemplary vertical cross-sectional view of the cladding structure on the local silicon interposer along A-A′ line in FIG. 17A after the chemical mechanical polishing (CMP) of flowable oxide or spin-on dielectric, stopping on the top vias and spacer cladding.

FIG. 18A is an exemplary top view of the cladding structure on the local silicon interposer after the partial etch back of flowable oxide or spin-on dielectric shown in FIGS. 17A and 17B.

FIG. 18B is an exemplary vertical cross-sectional view of the cladding structure on the local silicon interposer along A-A′ line in FIG. 18A after the partial etch back of flowable oxide or spin-on dielectric shown in FIGS. 17A and 17B.

FIG. 19A is an exemplary top view of the cladding structure on the local silicon interposer after the complete etch back of flowable oxide or spin-on dielectric shown in FIGS. 17A and 17B.

FIG. 19B is an exemplary vertical cross-sectional view of the cladding structure on the local silicon interposer along A-A′ line in FIG. 19A after the complete etch back of flowable oxide or spin-on dielectric is shown in FIGS. 17A and 17B.

FIG. 20A is an exemplary top view of a local silicon interposer after the completion of photoresist patterning on top vias following various dielectric depositions on the surface of the top vias and the local silicon interposer.

FIG. 20B is an exemplary vertical cross-sectional view of a local silicon interposer along the A-A′ line in FIG. 20A after the completion of photoresist patterning on top vias following various dielectric depositions on the surface of the top vias and the local silicon interposer.

FIG. 21A is an exemplary top view of a local silicon interposer after isotropic ion etching or wet etching following photoresist patterning on the surface of the top vias and the local silicon interposer.

FIG. 21B is an exemplary vertical cross-sectional view of a local silicon interposer along A-A′ line FIG. 21A after isotropic ion etching or wet etching following photoresist patterning on the top vias and the local silicon interposer surface.

FIG. 22A is an exemplary top view of a local silicon interposer after stripping photoresist from the surface of top vias and the local silicon interposer.

FIG. 22B is an exemplary vertical cross-sectional view of a local silicon interposer along A-A′ line in FIG. 22A after stripping of photoresist from the surface of the top vias and the local silicon interposer.

FIG. 23A is an exemplary top view of a local silicon interposer after the complete attachment of a grinding tape on the cladding structures of the surface of the top vias formed by wet etch or isotropic ion etch.

FIG. 23B is an exemplary vertical cross-sectional view of a local silicon interposer in A-A′ line in FIG. 23A after a complete attachment of a grinding tape on the cladding structures of the surface of the top vias formed by wet etch or isotropic ion etch.

FIG. 24A is an exemplary top view of a local silicon interposer after stripping a grinding tape from the surface of the local silicon interposer and the cladding structures formed by an isotropic etch or wet etch.

FIG. 24B is an exemplary vertical cross-sectional view of a local silicon interposer along A-A′ line in FIG. 24A after stripping a grinding tape from the surface of the local silicon interposer and the cladding structures formed by an isotropic etch or wet etch.

FIG. 25A is an exemplary top view of a local silicon interposer after a complete deposition of flowable oxide or spin-on dielectric on the surface of the local silicon interposer and cladding structures formed by wet etch or isotropic dry etch.

FIG. 25B is an exemplary vertical cross-sectional view of a local silicon interposer along A-A′ line in FIG. 25A after the complete deposition of flowable oxide or spin-on dielectric on the surface of the local silicon interposer and cladding structures formed by wet etch or isotropic dry etch.

FIG. 26A is an exemplary top view of the cladding structure on the local silicon interposer after the chemical mechanical polishing (CMP) of flowable oxide or spin-on dielectric, stopping on top vias.

FIG. 26B is an exemplary vertical cross-sectional view of the cladding structure on the local silicon interposer along A-A′ line in FIG. 26A after the chemical mechanical polishing (CMP) of flowable oxide or spin-on dielectric, stopping on top vias.

FIG. 27A is an exemplary top view of the cladding structure on the local silicon interposer after the partial etch back of flowable oxide or spin-on dielectric shown in FIGS. 26A and 26B.

FIG. 27B is an exemplary vertical cross-sectional view of the cladding structure on the local silicon interposer along A-A′ line in FIG. 27A after the partial etch back of flowable oxide or spin-on dielectric shown in FIGS. 26A and 26B.

FIG. 28A is an exemplary top view of the cladding structure 133 on the local silicon interposer after the complete etch back of flowable oxide or spin-on dielectric shown in FIGS. 26A and 26B.

FIG. 28B is an exemplary cross-sectional view of the cladding structure on the local silicon interposer along A-A′ line in FIG. 28A after the complete etch back of flowable oxide or spin-on dielectric shown in FIGS. 26A and 26B.

FIG. 29A is an exemplary top view of a local silicon interposer after anisotropic reactive ion etching or dry etching following a photoresist patterning on the surface of top vias and the local silicon interposer.

FIG. 29B is an exemplary vertical cross-sectional view of a local silicon interposer along A-A′ line in FIG. 29A after reactive ion etching or dry etching following photoresist patterning on the surface of the top vias and the local silicon interposer.

FIG. 30A is an exemplary top view of a local silicon interposer after stripping photoresist from the surface of the top vias and the local silicon interposer.

FIG. 30B is an exemplary vertical cross-sectional view of a local silicon interposer along A-A′ line in FIG. 30A after stripping photoresist from the surface of the top vias and the local silicon interposer.

FIG. 31A is an exemplary top view of a local silicon interposer after the complete attachment of a grinding tape on the cladding structures of the surface of top vias formed by an anisotropic reactive ion etch or dry etch.

FIG. 31B is an exemplary vertical cross-sectional view of a local silicon interposer along A-A′ line in FIG. 31A after the complete attachment of a grinding tape on the cladding structures of the surface of the top vias formed by reactive ion etch or dry etch.

FIG. 32A is an exemplary top view of a local silicon interposer after stripping a grinding tape from the surface of the local silicon interposer and the cladding structures formed by reactive ion etch or dry etch.

FIG. 32B is an exemplary vertical cross-sectional view of a local silicon interposer along A-A′ line in FIG. 32A after stripping off a grinding tape attached to the surface of the local silicon interposer and the cladding structures formed by reactive ion etch or dry etch.

FIG. 33A is an exemplary top view of a local silicon interposer after a complete deposition of flowable oxide or spin-on dielectric on the surface of the local silicon interposer and cladding structures formed by an anisotropic reactive ion etch or dry etch.

FIG. 33B is an exemplary vertical cross-sectional view of a local silicon interposer along A-A′ line in FIG. 33A after a complete deposition of flowable oxide or spin-on dielectric on the surface of the local silicon interposer and cladding structures formed by an anisotropic reactive ion etch or dry etch.

FIG. 34A is an exemplary top view of the cladding structure on the local silicon interposer after the chemical mechanical polishing (CMP) of flowable oxide or spin-on dielectric, stopping on top vias.

FIG. 34B is an exemplary cross-sectional view of the cladding structure on the local silicon interposer along A-A′ line in FIG. 34A after the chemical mechanical polishing (CMP) of flowable oxide or spin-on dielectric, stopping on top vias.

FIG. 35A is an exemplary top view of the cladding structure on the local silicon interposer after the partial etch back of flowable oxide or spin-on dielectric shown in FIGS. 34A and 34B.

FIG. 35B is an exemplary vertical cross-sectional view of the cladding structure on the local silicon interposer along A-A′ line in FIG. 35A after the partial etch back of flowable oxide or spin-on dielectric shown in FIGS. 34A and 34B.

FIG. 36A is an exemplary top view of the cladding structure on the local silicon interposer after the complete etch back of flowable oxide or spin-on dielectric shown in FIGS. 34A and 34B.

FIG. 36B is an exemplary vertical cross-sectional view of the cladding structure on the local silicon interposer along A-A′ line in FIG. 36A after the complete etch back of flowable oxide or spin-on dielectric shown in FIGS. 34A and 34B.

FIG. 37 is a three-dimensional perspective view taking measurements of the distance between the claddings, the height, the cladding thickness, and the via's diameter after the complete formation of a representative claim structure.

FIG. 38 is a process flow illustrating method steps to form a local silicon interposer with top via having a barrier structure according to various embodiments disclosed herein.

FIG. 39 is a process flow illustrating method steps to form a local silicon interposer with top via having a barrier structure according to various embodiments disclosed herein.

FIG. 40 is a process flow illustrating method steps to form a local silicon interposer with top via having a barrier structure according to various embodiments disclosed herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures.

Generally, all devices of the present disclosure may be rotated unless otherwise specified, and the spatially relative descriptors used herein may likewise be interpreted accordingly. Unless explicitly stated otherwise, each element having the same reference numeral is presumed to have the same material composition and to have a thickness within a same thickness range.

The various embodiments disclosed herein propose solutions to mitigate the problems that may arise due to metallic material migration, metallic material wire growth and metallic material loss by introducing via barrier structures (also referred to as a cladding structure) with an integrated dielectric barrier to prevent metallic material migration and wire formation. The via barrier structures enhance electrical performance and improve the semiconductor package reliability, making it suitable for high-performance computing (HPC).

The various embodiments disclosed herein are directed to high-performance computing (HPC) architecture, where silicon interposers stack memory, CPUs, and GPUs that may enhance the overall performance and bandwidth of the computer chips. High-performance applications such as artificial intelligence (AI) make use of heterogeneous integration, where logic chips and many memory chips are contained within a single package. The concept of heterogeneous integration plays an important role in high-performance computing (HPC) architecture. In this context, silicon interposers serve as a bridge and may enhance computer chips'overall performance and bandwidth. Notably, this approach is particularly relevant for artificial intelligence (AI) applications, which leverage the seamless coordination between logic chips and a substantial number of memory chips.

Metallic material vias (e.g., copper vias) may be used in interposers as materials such as copper, gold, silver, tungsten, etc., are excellent conductors that allow efficient signal transmission between different redistributed layers in the package.

During the interposer interconnection scheme, metallic material vias may be exposed to chemical reactions with subsequent processing. Such exposure may render the metallic material vias susceptible to electromigration, where the movement of metallic material atoms under current flow may cause metallic material wire growth, voids, or cracks that may cause circuit failure and affect the long-term reliability of the device. Proper barrier layers may be beneficial to prevent metallic material wire formation from affecting long-term reliability and ensure the electrical performance of the device.

According to an aspect of the present disclosure, vias (such as copper vias) formed with cladding or barrier structures for use in interposer and methods for forming the same are disclosed. The cladding or barrier structures may use different types of oxides, metal liners, and integration schemes to form the oxide cladding structures. The cladding or barrier structures may prevent metallic material reactions with grinding tape. The metallic material reactions might otherwise allow for the migration of metallic material atoms and/or the growth of undesired or unintended metallic material wires. The migration of metallic material atoms and/or the growth of undesired or unintended metallic material wires may otherwise be detrimental to the long-term reliability and electrical performance requirements of the device. The integration of the cladding layers not only mitigates against undesired or unintended metallic material wires that may result in related reliability issues but also ensures overall low dielectric constant in the layers and stress engineering opportunities for different types of interposers.

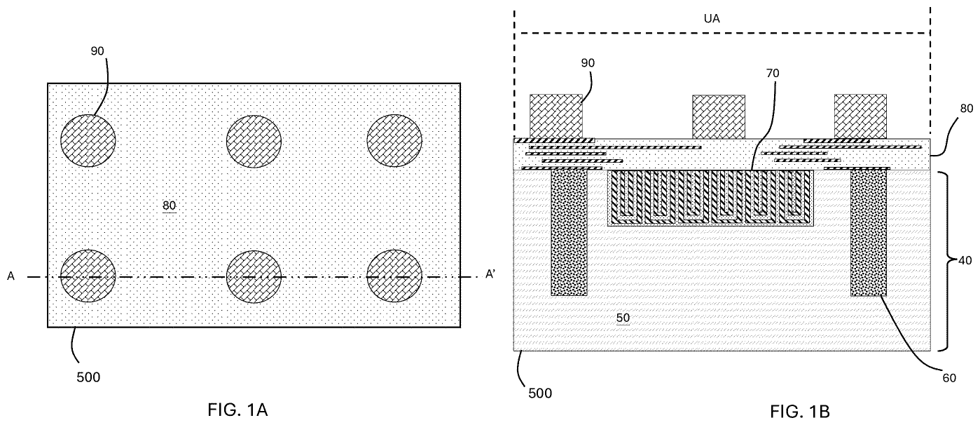

FIG. 1A illustrates a top view of the interposer 500 for use in a semiconductor package, showcasing the layout of top vias 90. FIG. 1A highlights the placement and distribution of the top vias 90 within the interposer 500, which facilitates vertical electrical connections between different layers and components of the semiconductor package. The top view in FIG. 1A provides a clear depiction of how the top vias 90 may be patterned to ensure optimal signal routing and power distribution across the interposer 500. In this embodiment, the distance between adjacent top vias 90 may be, but is not limited to, a range from approximately 1 to 500 micrometers. Such distances may provide flexibility in the design to accommodate various routing requirements. The height of the top vias 90 may be, but is not limited to, a range from about 1 to 100 micrometers, while their width may, but is not limited to, also vary from approximately 1 to 100 micrometers. These dimensions may be chosen to optimize electrical performance and reliability while maintaining the structural integrity of the interposer.

Referring to FIG. 1B, a first exemplary structure according to an embodiment of the present disclosure is illustrated. The exemplary structure of the unit area (UA) of interposer 500 includes a substrate 40. Generally, the substrate 40 comprises, and/or consists essentially of, at least one material selected from an insulating material, a semiconductor material, and a metallic material. In one embodiment, the substrate 40 may be a semiconductor substrate such as a commercially available silicon substrate. The substrate 40 may include a semiconductor material layer 50 at least at an upper portion thereof. The semiconductor material layer 50 may be a surface portion of a bulk semiconductor substrate or may be a top semiconductor layer of a semiconductor-on-insulator (SOI) substrate. In one embodiment, the semiconductor material layer 50 may include a single crystalline semiconductor material such as single crystalline silicon. In one embodiment, substrate 40 may include a single crystalline silicon substrate. A deep trench capacitor 70 may be formed within the interposer 500. The deep trench capacitor 70 may operate as a memory device, such as a DRAM memory unit. The memory device may be designed to optimize memory performance and integration in high-density semiconductor packages. The deep trench capacitor 70 may be formed by forming trenches that are etched deep into the silicon substrate and filled with a high-dielectric constant material and metal electrode to form the deep trench capacitor 70.

The local silicon interposer (LSI) 500 may incorporate vias 60 to facilitate high-speed and reliable electrical connections between various integrated circuits (ICs) in advanced semiconductor packages. Vias 60 within a local silicon interposer 500 may be formed vertically within the interposer substrate 40, The vias 60 may be formed by patterning and etching cavities within the substrate 40 and depositing an electrically conductive material such as copper within the cavities to form vias 60. An optional barrier layer liner (not shown) may also be conformally deposited into the etched cavity to line the cavity prior to the deposition of the electrically conductive material. Vias 60 may serve as a conduit for electrical signals and power distribution. By providing a direct electrical path between the redistribution layers (RDL) of different ICs, vias 60 may reduce signal latency and enhance bandwidth. Such properties are largely beneficial to high-performance computing applications. In subsequent processing, the vias 60 may contain separate contact areas at the bottom of LSI 500.

A redistribution layer (RDL) 80 may also be included with a local silicon interposer 500. The RDL 80 may provide the re-routing of electrical interconnections to facilitate high-density, high-performance packaging solutions. The fabrication process of the RDL 80 typically begins with the deposition of a dielectric layer on the interposer substrate 40, followed by the patterning, etching, and connecting of electrically conductive interconnects that may be formed within the dielectric layers. The electrically conductive interconnects may be formed from electroplated copper or any electrically conductive material. The electrically conductive material may be planarized and patterned to define the RDL traces, which are then covered with another dielectric layer for insulation and protection. This process may be repeated to create multiple layers within the RDL 80, allowing for complex routing schemes. The existence of the RDL 80 in the local silicon interposer 500 offers several advantages, including the ability to achieve fine-pitch interconnections, improved signal integrity through shorter and more direct routing paths, and enhanced integration density by enabling vertical stacking of dies. Top vias 90 may be formed as a portion of the redistribution layer (RDL) 80 that facilitates the vertical interconnection between different layers and components within the semiconductor package. As part of RDL 80, these top vias 90 provide a robust and highly conductive pathway that ensures efficient signal transmission and power delivery across the various integrated circuits. By enabling direct and reliable connections between the RDL 80 and other package elements, the top vias 90 may improve the overall functionality and performance of high-density, high-speed semiconductor device applications such as artificial intelligence, data centers, and high-performance computing. In some embodiments, a blanket layer of an electrically conductive material, such as copper, may be deposited or electroplated over the top layer of the RDL 80. The blanket layer may be masked photolithographically, patterned, and etched to form the individual top vias 90. In an alternative embodiment, a dielectric layer may be deposited over the top layer of the RDL 80 and patterned through a photolithographic process. The pattern may be transferred to the dielectric layer and subsequently etched to form cavities over the RDL 80. The electrically conductive metal material may be deposited or electroplated in the cavities to form the top vias 90. In one embodiment, the interposer includes a combination of vias 60 and RDL 80, which are formed within a semiconductor substrate to achieve high-performance electrical connections. The device may further incorporate the deep trench capacitors 70, which enhance the device's overall functionality by providing additional memory integration within the interposer 500.

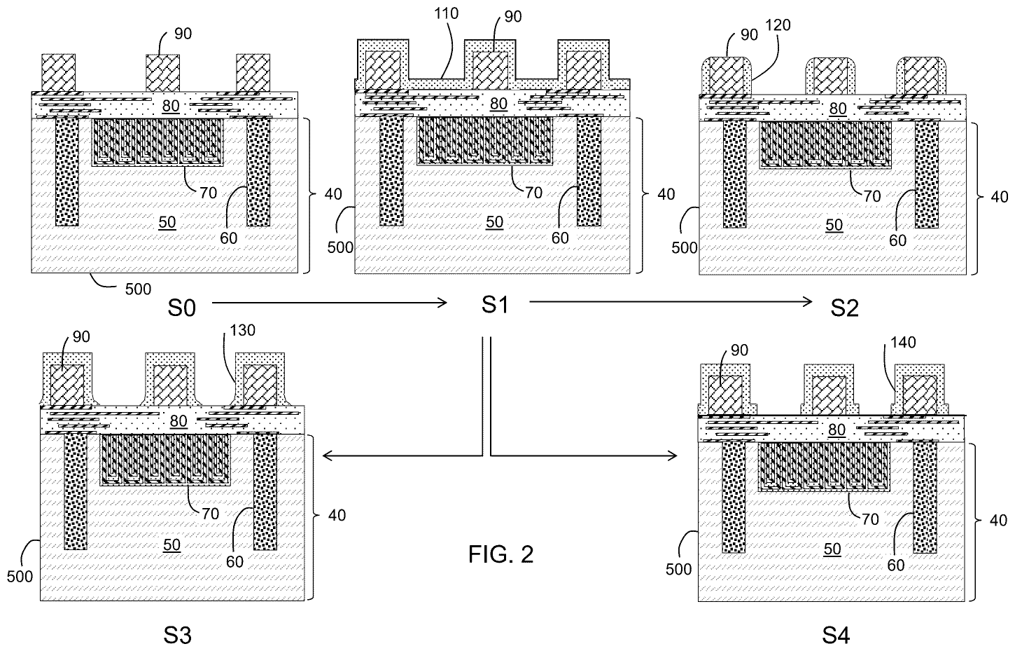

FIG. 2 illustrates a sequence of fabrication steps to form intermediate building blocks of cladding structures 110, 120, 130, and 140 on the top vias 90 that are part of a local silicon interposer (LSI) die. The various intermediate structures 500 illustrate different types of intermediate cladding layers that may be used to form the various embodiment interposer structures. For example, four separate embodiment interposer structures 500 may be formed. In step S0, an initial local silicon interposer (e.g., LSI 500 as shown in FIG. 1B) is provided. The process begins with a cladding layer, comprising any number of oxides, metal liners, or combined layers, that may be deposited over the top vias 90 and redistribution layer 80 of interposer 500, which includes deep trench capacitor 70 and vias 60. This cladding layer (also referred to as a barrier layer) may provide foundational barriers and insulation. In a first intermediate embodiment structure shown in step S1, a blanket layer cladding structure 110 may be formed by conformally depositing a cladding layer over the top vias 90 and redistribution layer 80 of interposer 500. In step S2, a blanket layer cladding structure 120, which may be referred to as a self-aligned spacer cladding structure 120 may be formed around top vias 90 by first depositing the cladding layer over the top vias 90 and redistribution layer 80 of interposer 500 and then performing a directional anisotropic etching process that leaves the spacer material only on the sidewalls of the top vias 90, ensuring proper alignment and protection. Alternative to step S2, a blanket layer cladding structure 130 may be formed in step S3 or a further blanket layer cladding structure 140 maybe formed in S4. Both step S3 and step S4 may be performed on the first embodiment blanket layer cladding structure 110 of step S1. Both steps S3 and S4 may involve applying a photoresist patterning to define areas for subsequent etching processes, thereby forming respective tapered-foot cladding structure 130 and L-foot cladding structure 140. To form the tapered-foot cladding structure 130, in step S3, wet etching may be used to etch away the exposed areas defined by the photoresist, leading to an undercut beneath the photoresist. This undercut results in a tapered-foot shape at the foot of the cladding structures, forming the tapered-foot cladding structures 130. Alternative to the tapered-foot cladding structure 130 formed through step S3, a L-foot cladding structure 140 may be formed in step S4, which involves anisotropic reactive ion etching (RIE) or dry etching, which is a directional process. These directional processes etch the exposed areas vertically, creating an “L” shape at the foot of the cladding structures, forming the L-foot cladding structure 140 and providing higher precision and control.

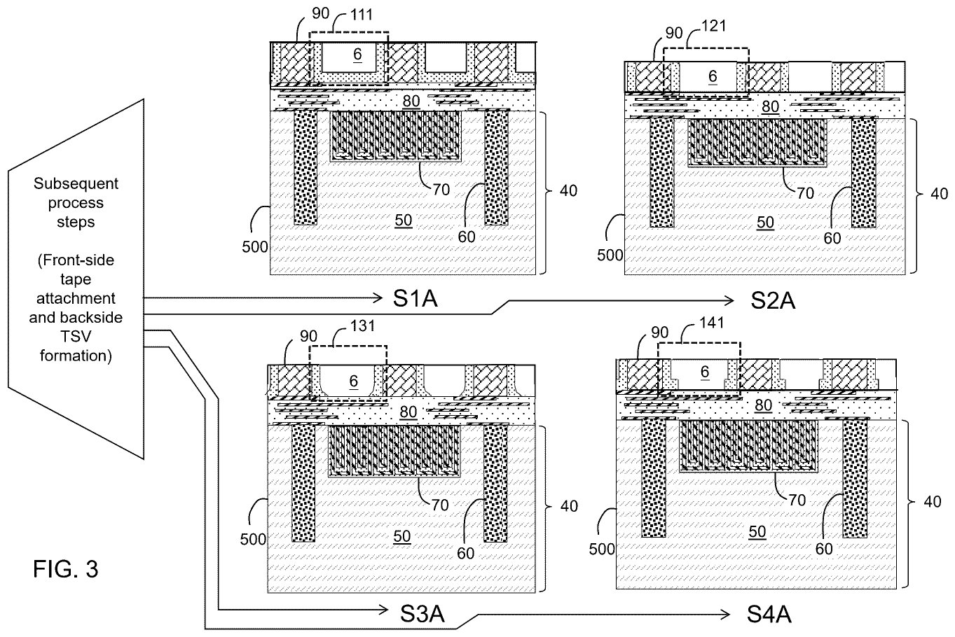

FIG. 3 illustrates subsequent process steps after steps S1, S2, S3, and S4, followed by steps S1A, S2A, S3A, or S4A, respectively. Each of steps S1A, S2A, S3A, and S4A may form blanket layer cladding structures 111, the self-aligned spacer cladding structure 121, the tapered-foot cladding structure 131, or the L-foot cladding structure 141, respectively, representing various embodiment structures. Before the subsequent process steps, a protective tape or grinding tape 5 may be attached to safeguard the top vias 90 during subsequent processing steps, particularly during the grinding of the backside of the die or wafer and handling. These subsequent process steps may involve additional processing on the backside of the through-silicon vias (TSVs), including further oxide layer deposition, patterning, and etching as required to complete the TSV formation. Cladding structures (e.g., 111, 121, 131, 141) cover the top vias 90, ensuring that the top vias 90 are well-protected against any chemical reactions from grinding tape 5, which enhances the long-term reliability of the device.

In step S1A, the first embodiment intermediate blanket layer cladding structure 110 is further processed. A blanket layer cladding structure 111 may be formed by depositing a dielectric 6 around top vias 90 in the intermediate blanket layer cladding structure 110 and planarizing the flowable or spin-coat dielectric 6. The flowable or spin-coat dielectric 6 may be deposited over the intermediate blanket layer cladding structure 110 in step S1 of FIG. 2. A chemical mechanical polishing (CMP) may be performed over dielectric 6 and portions of the cladding layer until the top surface of top via 90 may be exposed. The conformal cladding layer may be left only on the sidewalls of the top vias 90 and the surface of the redistribution layer 80, along with flowable oxide or spin-on dielectric 6, ensuring proper alignment and protection of the device.

In alternative step S2A, the self-aligned spacer cladding structure 120 of step S2 in FIG. 2 may be further processed. A cladding structure 121 may be formed by planarizing portions of the flowable or spin-coat dielectric 6 over top vias 90 and portions of the cladding layer over the top of vias 90. The flowable or spin-coat dielectric 6 may be deposited over the self-aligned spacer cladding structure 120 in step S2 of FIG. 2. A chemical mechanical polishing (CMP) may be performed over portions of the dielectric 6 and cladding layer until the top surface of top via 90 may be exposed. In the self-aligned spacer cladding structure 121, the conformal cladding layer remains only on the sidewalls of the top vias 90 in conjunction with flowable oxide or spin-on dielectric 6, ensuring proper alignment and protection of the device.

In step S3A, the tapered-foot cladding structure 130 of step S3 in FIG. 2 may be further processed. A tapered-foot cladding structure 131 may be formed around top vias 90 by planarizing portions of the flowable or spin-coat dielectric 6 and portions of the conformal cladding layer over top via 90. The flowable or spin-coat dielectric 6 may be deposited over the tapered-foot cladding structure 130 in step S3 of FIG. 2. A chemical mechanical polishing (CMP) may be performed to planarize the top of dielectric 6 and cladding layer until the top surface of top vias 90 may be exposed.

The resulting structure is the tapered-foot cladding structure 131, in which the conformal cladding layer remains only on the sidewalls of the top vias 90 and may include flowable oxide or spin-on dielectric 6 formed between vias 90, ensuring proper alignment and protection of the device.

In step S4A, the L-foot cladding structure 140 of step S4 in FIG. 2 is further processed. A L-foot cladding structure 141 may be formed around top vias 90 by planarizing flowable or spin-coat dielectric 6 over the top vias 90. The flowable or spin-coat dielectric 6 may be deposited over the L-foot cladding structure 140 in step S4 of FIG. 2. A chemical mechanical polishing (CMP) may be performed on the top surface of dielectric 6 and cladding layer until the top surface of top vias 90 may be exposed. The resulting structure is the L-foot cladding structure 141, in which the cladding layer is left only on the sidewalls of the top vias 90 and may include flowable oxide or spin-on dielectric 6, ensuring proper alignment and protection of the device.

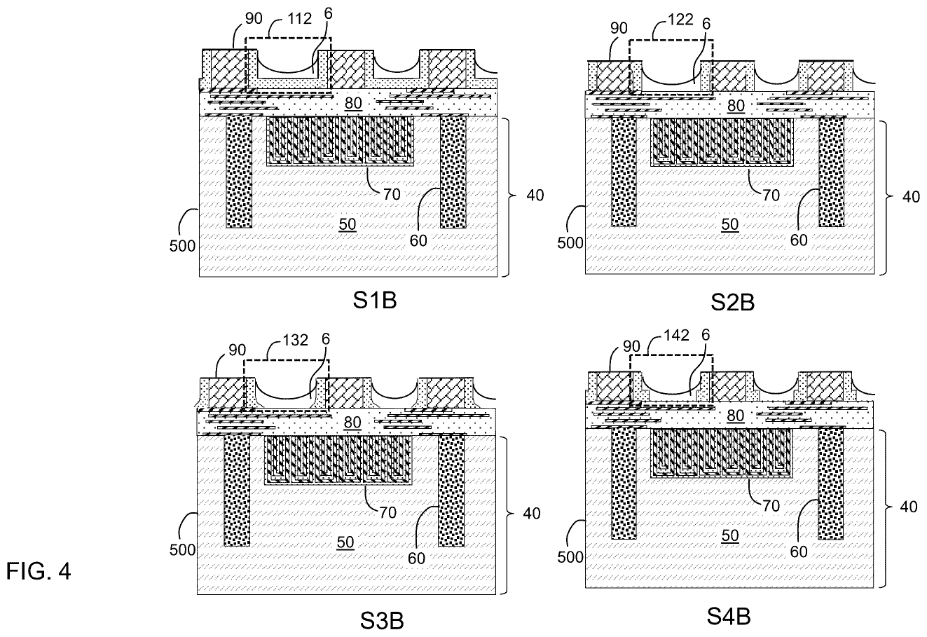

FIG. 4 illustrates subsequent process steps S1B, S2B, S3B, and S4B after steps S1A, S2A, S3A, and S4A respectively. Each of steps S1B, S2B, S3B, and S4B may form blanket layer cladding structure 112, the self-aligned spacer cladding structure 122, the tapered-foot cladding structure 132, or the L-foot cladding structure 142, respectively, representing various embodiment structures. These subsequent processes may include partial etch back of flowable or spin-coat dielectric 6 by wet or isotropic etch, ensuring that the top vias 90 are properly exposed and clean.

In step S1B, the blanket layer cladding structure 111 of step S1A in FIG. 3 is further processed to form blanket layer cladding structure 112. A blanket layer cladding structure 112 may be formed around top vias 90 by further planarizing flowable or spin-coat dielectric 6to partially etch back the flowable or spin-coat dielectric 6, thereby exposing top vias 90. The conformal cladding layer remains only on the sidewalls of the top vias 90 and the surface of the redistribution layer 80, in conjunction with recessed flowable oxide or spin-on dielectric 6 by etch back process, ensuring proper alignment and protection of the device.

In step S2B, the self-aligned spacer cladding structure 121 of step S2A in FIG. 3 is further processed to form self-aligned spacer cladding structure 122. A self-aligned spacer cladding structure 122 may be formed around top vias 90 by further planarizing flowable or spin-coat dielectric 6 to partially etch back the flowable or spin-coat dielectric 6, thereby exposing top vias 90. The resulting structure may be the self-aligned spacer cladding structure 122, wherein the cladding layer remains only on the sidewalls of the top vias 90 in conjunction with recessed flowable oxide or spin-on dielectric 6 by etch back process, ensuring proper alignment and protection of the device.

In step S3B, the tapered-foot cladding structure 131 of step S3A in FIG. 3 is further processed to form the tapered-foot cladding structure 132. A tapered-foot cladding structure 132 may be formed around top vias 90 by further planarizing flowable or spin-coat dielectric 6 to partially etch back the flowable or spin-coat dielectric 6, thereby exposing top vias 90. The resulting structure may be the tapered-foot cladding structure 132, wherein the cladding layer remains only on the sidewalls of the top vias 90 in conjunction with recessed flowable oxide or spin-on dielectric 6 by etch back process, ensuring proper alignment and protection of the device.

In step S4B, the L-foot cladding structure 141 of step S4A in FIG. 3 is further processed to form the L-foot cladding structure 142. A L-foot cladding structure 142 may be formed around top vias 90 by further planarizing flowable or spin-coat dielectric 6 to partially etch back the flowable or spin-coat dielectric 6, thereby exposing top vias 90. The resulting structure may be referred to as a “L” shaped cladding structure 142, wherein the cladding layer remains only on the sidewalls of the top vias 90 in conjunction with recessed flowable oxide or spin-on dielectric 6 by etch back process, ensuring proper alignment and protection of the device.

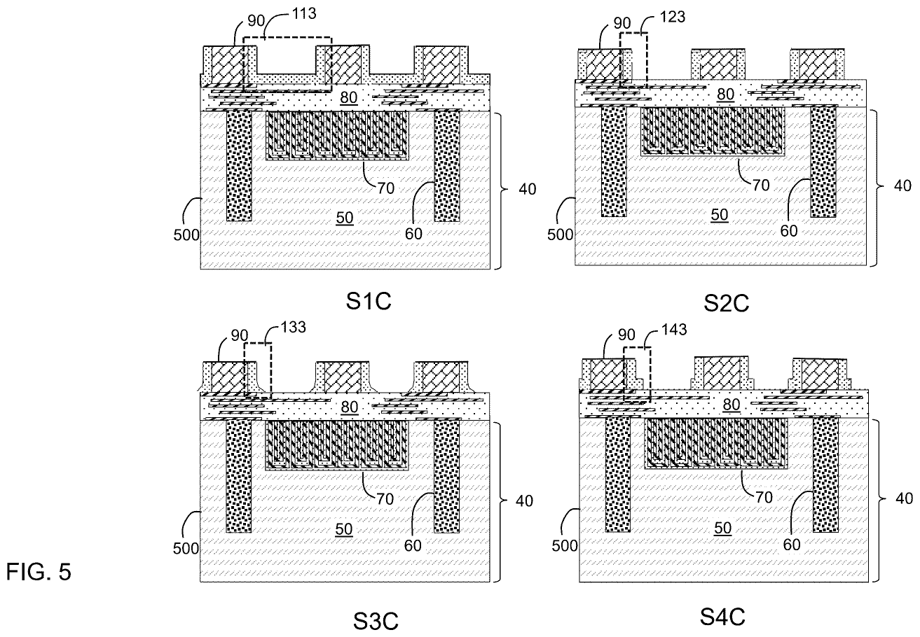

FIG. 5 illustrates subsequent process steps S1C, S2C, S3C, and S4C after steps S1B, S2B, S3B, and S4B, respectively from FIG. 4 to form blanket layer cladding structures 113, the self-aligned spacer cladding structure 123, the tapered-foot cladding structure 133, or the L-foot cladding structure 143, respectively, representing various embodiment structures. These subsequent processes may include a complete etch back of flowable or spin-coat dielectric 6 by wet or isotropic etch, ensuring that the top vias 90 are properly exposed and clean.

In step S1C, the blanket layer cladding structure 112 of FIG. 4 is further processed to form blanket cladding structure 113. A blanket layer cladding structure 113 may be formed around top vias 90 by planarizing flowable or spin-coat dielectric 6, to remove the blanket cladding layer from over the via 90 by chemical mechanical polishing (CMP), and completely removing flowable or spin-coat dielectric 6, thereby exposing top vias 90. In the blanket layer cladding structure 113, the conformal blanket cladding layer remains only on the sidewalls of the top vias 90 and the surface of the redistribution layer 80, ensuring proper alignment and protection of the device.

In step S2C, the self-aligned spacer cladding structure 122 of FIG. 4 is further processed to form self-aligned spacer cladding structure 123. A self-aligned spacer cladding structure 123 may be formed around top vias 90 through planarizing flowable or spin-coat dielectric 6, removing the cladding layer from over the via 90by chemical mechanical polishing (CMP), and completely removing flowable or spin-coat dielectric 6, thereby exposing top vias 90. In the self-aligned spacer cladding structure 123, the cladding layer remains only on the sidewalls of the top vias 90, ensuring proper alignment and protection of the device.

In step S3C, the tapered-foot cladding structure 132 of FIG. 4 is further processed to form tapered-foot cladding structure 133. A tapered-foot cladding structure 133 may be formed around top vias 90 through planarizing flowable or spin-coat dielectric 6, removing the cladding layer from over the via 90by chemical mechanical polishing (CMP), and completely removing flowable or spin-coat dielectric 6, thereby exposing top vias 90. In the tapered-foot cladding structure 133, the cladding layer remains only on the sidewalls of the top vias 90, ensuring proper alignment and protection of the device.

In step S4C, the L-foot cladding structure 142 of FIG. 4 is further processed to form L-foot cladding structure 143. A L-foot cladding structure 143 may be formed around top vias 90 through planarizing flowable or spin-coat dielectric 6, removing the cladding structure 140 from over the via 90by chemical mechanical polishing (CMP), and completely removing flowable or spin-coat dielectric 6, thereby exposing top vias 90. In the L-shaped-foot cladding structure 143, the cladding layer remains only on the sidewalls of the top vias 90, ensuring proper alignment and protection of the device.

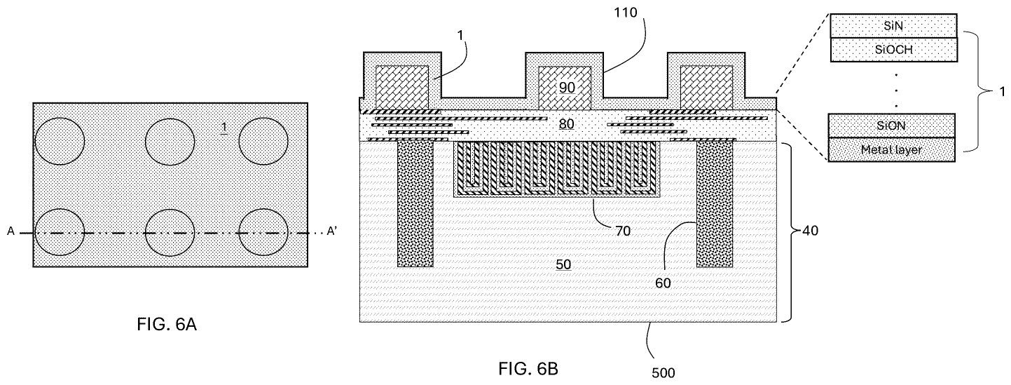

Referring to the step S1, FIG. 6A illustrates the top view of the deposition of a cladding layer comprising multi-layered blanket oxides and metal liner formed on top vias 90 and redistribution layer 80 to form a blanket layer cladding layer 1. FIG. 6B presents a vertical cross-sectional view along the line A-A′ in FIG. 6A, detailing the formation of the blanket layer cladding structure 110 formed around the top vias 90. The cladding layer may include, but is not limited to, various metal liners such as CuOx on the via surface, Ta, Ti, TaN, TiN, TiC, TaC, TiCN, TaCN, Mo, or MoN, followed by oxide layers. This cladding layer may also include, but is not limited to, SiOCHx, SiOx, SiNx, and SiON, with “x” ranging from 0.1 to less than 1. The thickness of these layers may vary depending on the specific application, and the sequence in which they are deposited may also differ. For example, the cladding structure 112, 122, 132, 142, 113, 123, 133, and 143 may place SiN as a final layer of cladding layers in contact with spin-coat dielectric 6. This SiN thickness may be thicker than other layers in the cladding layer, rendering a differential etch rate. In some applications, certain layers may be omitted entirely. For example, the blanket layer cladding structures 110, 111, 112, and 113 may not include metal layers. The cladding layers possess properties that include, but are not limited to, a barrier conductivity of less than or equal to 10-⁻¹ (Ω-m)⁻¹ and provide sidewall coverage rates greater than 70%. The deposition processes for these layers may include, but are not limited to, chemical vapor deposition (CVD), physical vapor deposition (PVD), or atomic layer deposition (ALD) to ensure precise thickness control and uniform coverage. The metal liners and/or oxides, alone or in any combination, effectively encapsulate the metal vias, preventing metal atom migration, such as metallic material and wire growth, and maintaining the structural integrity of the vias.

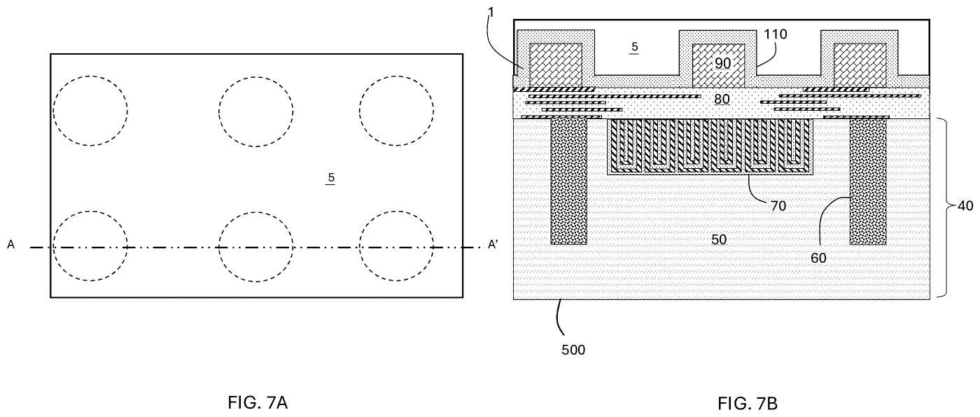

A detailed view of the grinding tape 5 attachment is shown with the first embodiment intermediate blanket layer cladding structure 110 in FIGS. 7A and 7B. FIG. 7A shows a top-down view of the first embodiment intermediate blanket layer cladding structure 110, and FIG. 7B presents a vertical cross-sectional view along the plane A-A′ in FIG. 7A. This process of the grinding tape 5 attachment provides mechanical support and protection to the delicate structures of the LSI during subsequent grinding processes, covering the top vias 90 and other exposed elements. This grinding tape 5 ensures that the top vias 90 and the interposer structure are retained and remain intact and free from damage or contamination from external sources.

However, there may be reliability concerns regarding the chemical interaction between the top vias 90 and the grinding tape 5. Specifically, there is a risk of chemical reactions, such as metal wire or metal atom migration at the interface between the vias 90 and the tape residue or materials. Such migration may lead to the formation of intermetallic compounds or diffusion of atoms, which may compromise the electrical performance and long-term reliability of the vias. To mitigate these issues, the use of cladding layer(s) in the various embodiment intermediate blanket layer cladding structures 110, 120, 130, 140 may be beneficial for the top vias 90. This cladding layer may prevent direct contact between top vias 90 and the grinding tape 5 residue or materials, thereby reducing the risk of chemical reactions and metallic atom migration. By maintaining the integrity of the top vias 90, this cladding layer ensures that the electrical characteristics remain stable and reliable throughout the device's lifespan.

The use of a cladding layer in the various embodiment structures is a beneficial step in addressing potential reliability issues during the grinding process.

During the grinding process, a subsequent formation of through-silicon vias (TSVs) from the backside of the LSI may occur and involve creating vertical interconnects. The backside TSV process ensures efficient electrical pathways and robust mechanical support for the entire package structure. This grinding tape 5 attachment step may be a part of TSV formation process, ensuring that the vias 90 and RDL 80 receive protection while the vias 60 are accurately exposed for the TSV formation and aligned for seamless integration into another die or interposers.

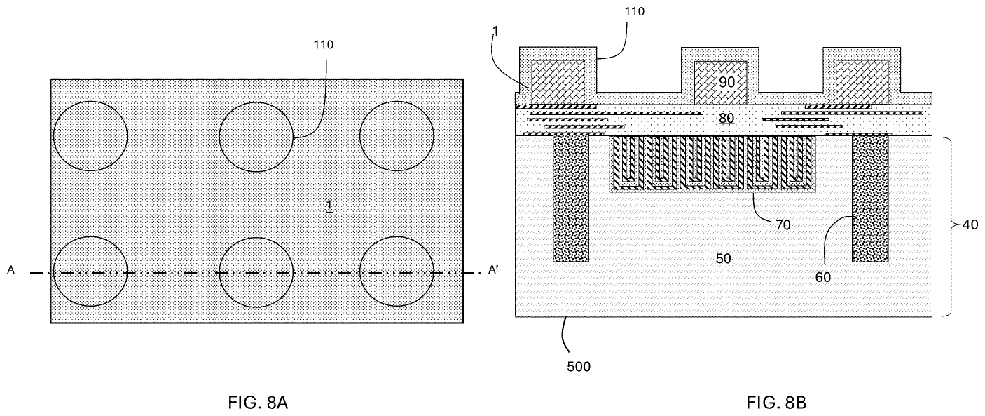

A detailed view of stripping grinding tape 5 and cleaning process is shown with the first embodiment intermediate blanket layer cladding structure 110 in FIGS. 8A and 8B. FIG. 8A shows a top-down view of the first embodiment intermediate blanket layer cladding structure 110, and FIG. 8B presents a vertical cross-sectional view along the plane A-A′ in FIG. 8A. The first embodiment intermediate blanket layer cladding structure 110 may be retained and remain intact during the grinding tape 5 attachment, detachment, and cleaning. The tape detachment process may begin with controlled heating to soften the adhesive of the protective tape or grinding tape 5 applied. The detachment and a solvent cleaning step may follow. Solvents such as isopropyl alcohol (IPA) or acetone may be applied to dissolve and remove the adhesive without damaging the underlying silicon, copper, or other metal features. In any step, deionized (DI) water rinse may be used to eliminate any residual solvent, thereby preventing ionic contamination. In some cases, a plasma cleaning step may be utilized. For example, oxygen or nitrogen plasma may effectively remove any remaining organic contaminants at the microscopic level, ensuring a pristine surface.

However, in rare cases, grinding tape 5 residue or materials remain and/or react with top vias 90 after cleaning steps. The use of a cladding layer in the various embodiment cladding structures ensures that the integrity of the top vias 90 is not compromised by preventing direct contact with tape residue and that the electrical characteristics remain stable and reliable throughout the device's lifespan. The use of a cladding layer in the various embodiment blanket layer cladding structures is a beneficial step in addressing potential reliability issues during complicated semiconductor package processes.

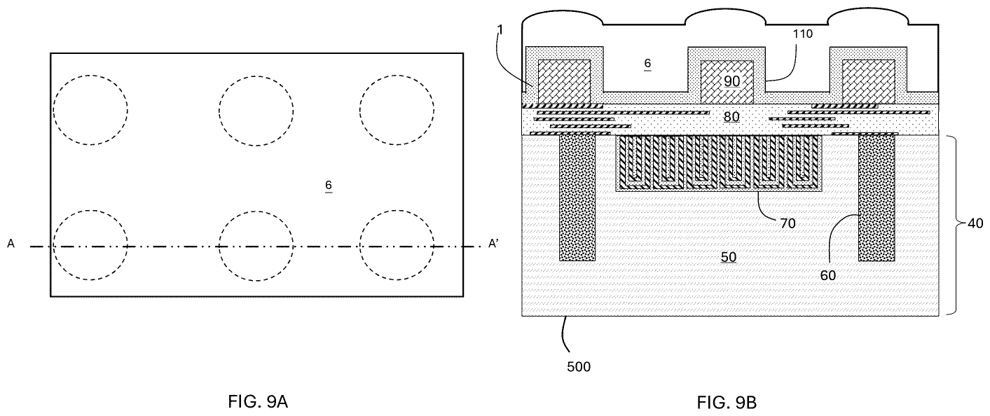

FIGS. 9A and 9B illustrate the application of a flowable oxide deposition or spin-coat dielectric 6 process onto the LSI 500. FIG. 9A shows a top view of the first embodiment intermediate blanket layer cladding structure 110. FIG. 9B shows a cross-sectional view along line A-A′ of the first embodiment intermediate blanket cladding structure 110. After the tape detachment and cleaning processes as described in FIGS. 8A and 8B, a flowable oxide deposition or spin-coat dielectric 6 may be applied to cover the surface of the LSI 500. For example, this process may begin with the preparation of a flowable oxide solution, typically comprising siloxane-based materials such as tetraethyl orthosilicate (TEOS), SiOCH, or organosilicates dissolved in a suitable solvent. The flowable oxide solution may be dispensed onto the center of the die. The spin coater may be set to rotate at a high speed, typically, but is not limited to, between 1000 to 5000 RPM, depending on the desired thickness and uniformity of the oxide layer. The centrifugal force generated by the spinning action spreads the flowable oxide solution evenly across the surface of the die, filling in any gaps and ensuring a uniform coating. During the spinning process, the solvent in the flowable oxide solution begins to evaporate, leaving behind a uniform thin film of oxide. This film serves as a planarization layer, filling in the topography and creating a smooth surface. The typical thickness of the spin-coated oxide layer ranges from a few nanometers to a few hundred micrometers. The coated LSI 500 is then subjected to a curing process to harden the oxide layer. This curing step typically involves heating the die to a temperature between 150° C. and 400° C. for a duration ranging from a few minutes to a few hours. The heat treatment helps to further densify the oxide layer and improve its mechanical properties.

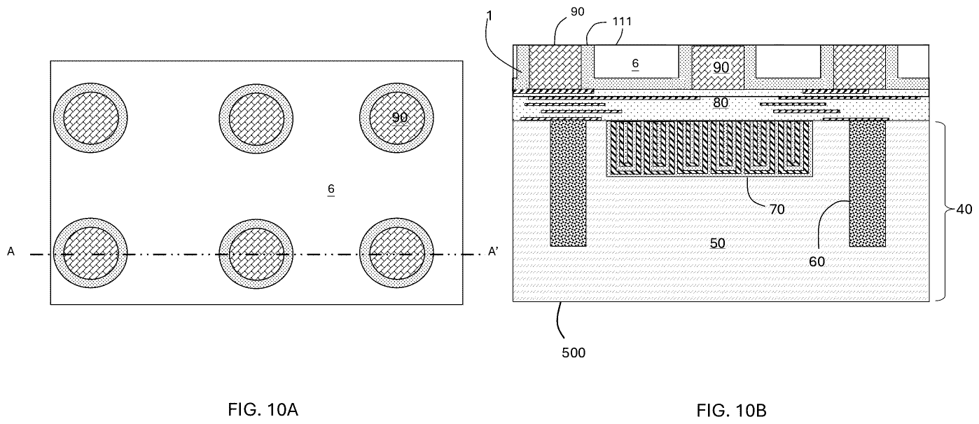

FIGS. 10A and 10B illustrate a blanket layer cladding structure 111 and depict the detailed view of forming and exposing the blanket layer cladding structure 111, which may include dielectric 6, ensuring the exposure of the top vias 90. FIG. 10A presents a top view of the blanket layer cladding structure 111 after the exposure of the top vias 90 by chemical mechanical polishing (CMP) step SIA, and FIG. 10B shows a vertical cross-sectional view along line A-A′ in FIG. 10A. Following flowable oxide deposition or spin-coat dielectric 6, Chemical Mechanical Planarization (CMP) in step S1A is applied to remove portions of dielectric 6 and cladding layer over the top surface of vias 90, stopping on the top vias 90. The CMP step S1A is used to remove the excess dielectric 6 and planarize the surface. The CMP slurry may contain abrasives such as silica or alumina, suspended in a chemically reactive solution. The reactive solution may include oxidizers, such as hydrogen peroxide, and complexing agents to facilitate the removal of the dielectric 6 and planarize the surface. During the CMP step SIA, the wafer may be pressed against a rotating polishing pad while the slurry is dispensed. This action mechanically removes dielectric 6, portions of the cladding material blanket layer on the surface of top vias 90 and any other residues from the surface. The process may be carefully monitored to ensure that it stops precisely at the top vias 90, exposing the top vias 90 while maintaining a smooth and even surface. After the initial CMP step, a touch-up CMP may be performed to ensure the complete exposure of the top vias 90 and to remove any remaining dielectric 6 or further process to remove any metal liner in the cladding material blanket layer on the top vias 90. The blanket layer cladding structure 111 may not include metal liners in the cladding layer as shown in FIG. 6B. Alternatively, the removal of dielectric 6 and cladding material blanket layer on the top surface of the top vias 90 may be achieved by blanket anisotropic and/or isotropic dry etch, alone or in any combination. The described process results in a well-defined and planarized blanket layer cladding structure 111, with the top vias 90 exposed and ready for further integration. For example, Cu-to-Cu interconnection may be integrated in furtherance of a complex packaging technology, such as a high bandwidth memory (HBM) packaging. This method may be identically applied to other embodiment intermediate cladding structures such as 120, 130, and 140, forming embodiment intermediate cladding structures 121, 131, and 141, respectively, ensuring uniformity and consistency across different regions of the LSI 500.

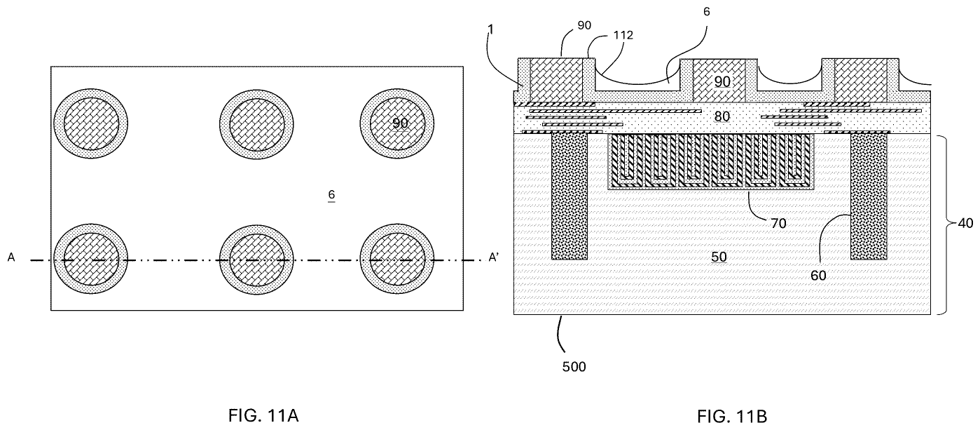

FIGS. 11A and 11B illustrate a blanket layer cladding structure 112 and depict the detailed view of forming and exposing blanket layer cladding structure 112, which may include recessed dielectric 6, ensuring the exposure of the top vias 90. Following the chemical mechanical polishing (CMP) in step S1A, an oxide etch back process, step S1B, is performed. The etch back process, step S1B, involves the selective removal of the spin-coat dielectric 6 to form the blanket layer cladding structure 112,. The etch back may be achieved using a wet etch chemistry that selectively attacks the dielectric 6 but not the top vias 90. The etchant used may be, but is not limited to, a buffered oxide etch (BOE) or similar chemical solution such as diluted HF (DHF). The etch back process, step S1B, ensures that the top vias 90 are fully exposed, creating a clean and well-defined interface for further processing and further recessing dielectric 6. The cladding structure 112 is achieved by a partial etch back. The etch rate difference between the blanket cladding layer and dielectric 6 makes it possible for dielectric 6 to etch faster than blanket cladding layer. The etch rate difference between flowable dielectric 6 and blanket cladding layer is attributed to variations in their processing conditions, material characteristics, and chemical reactivity. The cladding layer in blanket layer cladding structure 112 may be processed at higher temperatures ranging from 200° to 400° C., exhibits a denser and more robust structure compared to spin-coat dielectric 6. This increased density results in a slower etch rate when exposed to chemical etchants such as buffered oxide etch (BOE). Conversely, flowable oxide, processed at lower temperatures ranging from room temperature to 200° C., remains less dense and more porous, leading to a higher etch rate under the same etching conditions. The material properties and differential reactivity to etchants ensure that cladding layer provides greater protection and stability, while dielectric 6 is more easily patterned and removed during fabrication. The etch rate of dielectric 6 may be, but not limited to, 2x to 4x higher compared to cladding layer due to differences in their material characteristics and processing conditions. Alternatively, the high contrast of etch rate may be achieved by placing SiN layer as the outermost layer of the cladding layer. SiN etch rate is more than 2x slower than spin-coat dielectric 6 under the same etchant. the blanket layer cladding structure 112 may not include metal liners in the cladding layer. This selective etch back process, step S1B, may expose the top vias 90 while retaining a blanket cladding layer on the sidewall of the blanket cladding structure 112 during the etch back process, step S1B, such that various interconnection schemes are adaptable on the top surface of the top via. For example, the spatial area rendered by etch back may be beneficial for a high bandwidth memory (HBM) package in the use of micro-bump and reflow packaging with polymer underfill. This method may be identically applied to other embodiment intermediate cladding structures such as 121, 131, and 141, forming embodiment intermediate cladding structures 122, 132, and 142, respectively, ensuring uniformity and consistency across different regions of the LSI 500.

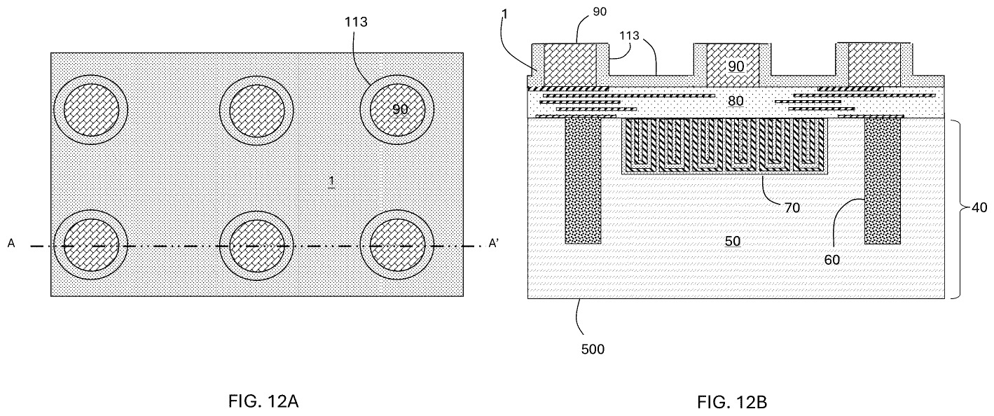

FIGS. 12A and 12B illustrate blanket layer cladding structure 113 and depict the detailed view after the complete etch back (i.e., removal) step S1C of dielectric 6 over the surface of RDL 80. Following step S1A, the etch back step S1C may be applied to achieve a blanket layer cladding structure 113, removing dielectric 6 over the surface of redistribution layer (RDL) 80 while exposing the top surface of the top vias 90 and maintaining conformal cladding layer over RDL 80, and on the sidewall of top vias 90 of the local silicon interposer 500, such that various interconnection schemes are adaptable on the top surface of the top via. For example, the spatial area rendered by etch back may be beneficial for a high bandwidth memory (HBM) package in the use of micro-bump and reflow packaging with polymer underfill. The blanket layer cladding structure 113 may not include metal liners in the intermediate blanket layer cladding structure 110. This method may be identically applied to other embodiment intermediate cladding structures such as 121, 131, and 141, forming embodiment intermediate cladding structures 123, 133, and 143, respectively, ensuring uniformity and consistency across different regions of the LSI 500.

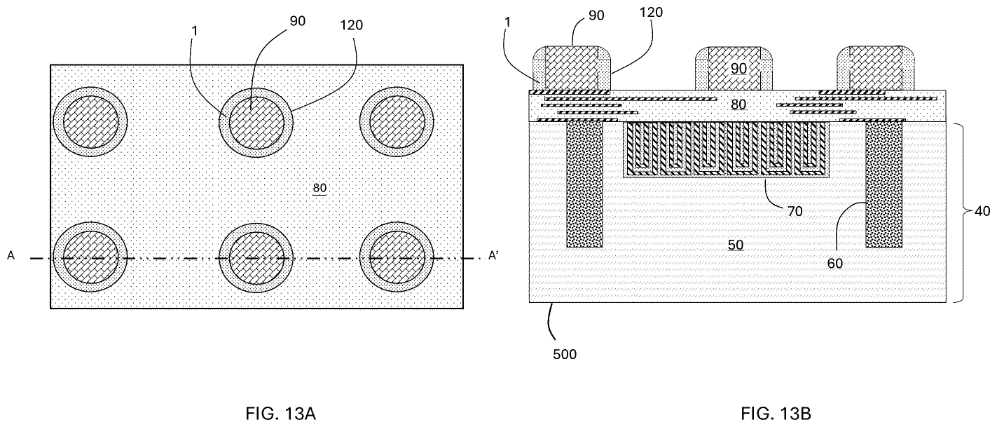

Referring to the step S2, FIGS. 13A and 13B illustrate the formation of a self-aligned spacer intermediate cladding structure 120 after an anisotropic directional reactive ion etch or dry etch process, showcasing the configuration and arrangement of the self-aligned spacer intermediate cladding structure 120 around the top vias 90. FIG. 13B presents a cross-sectional view along the line A-A′ in FIG. 13A, detailing the formation of the self-aligned spacer intermediate cladding structure 120 around the top vias 90. Initially, as detailed in step S1, a first embodiment intermediate blanket layer cladding structure 110 may formed by conformally depositing a cladding material blanket layer over the top vias 90 and redistribution layer 80, as shown in FIG. 6B.

Following the conformal deposition of the cladding material blanket layer, an anisotropic dry etch process may be used to remove the cladding material from the horizontal surfaces while leaving the vertical sidewalls retained and intact, forming the self-aligned spacer intermediate cladding structure 120. The etch chemistry for this process typically involves, but is not limited to, fluorocarbon-based gases such as CF4, CHF3, or C4F8, which selectively etch the oxide materials while stopping on the underlying metal liners. A different etch chemistry may be used to etch the metal liners, such as Ti, TiN, Ta, TaN, TaC, TiC, TaCN, TiCN, or MoN. Chlorine-based or bromine-based gases, such as Cl₂, BCl₃, or HBr, may be used for their effectiveness in etching metal materials, and the etch process is carefully controlled to stop on the surface of the redistribution layer (RDL) 80, preventing damage to the underlying layers. After the dry etch process, selective chemical wet cleaning may be performed to remove any residual etch by-products and ensure the surface's cleanliness.

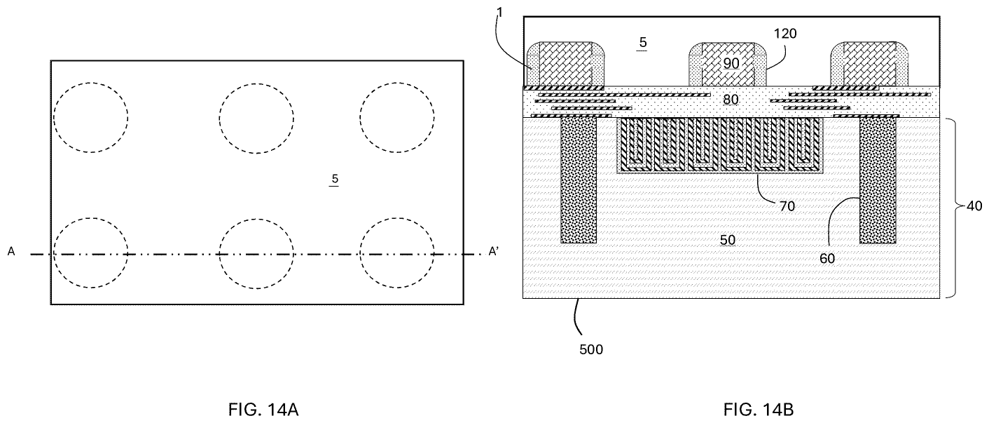

A detailed view of the grinding tape 5 attachment is shown with the self-aligned spacer intermediate cladding structure 120 in FIGS. 14A and 14B. FIG. 14A shows a top-down view of the self-aligned spacer intermediate cladding structure 120, and FIG. 14B presents a vertical cross-sectional view along the plane A-A′ in FIG. 14A. This process of the grinding tape 5 attachment provides mechanical support and protection to the delicate structures of the LSI die during subsequent grinding processes, covering the top vias 90 and other exposed elements. For brevity, similar method steps that have been discussed above with respect to FIG. 7 may have a shortened description.

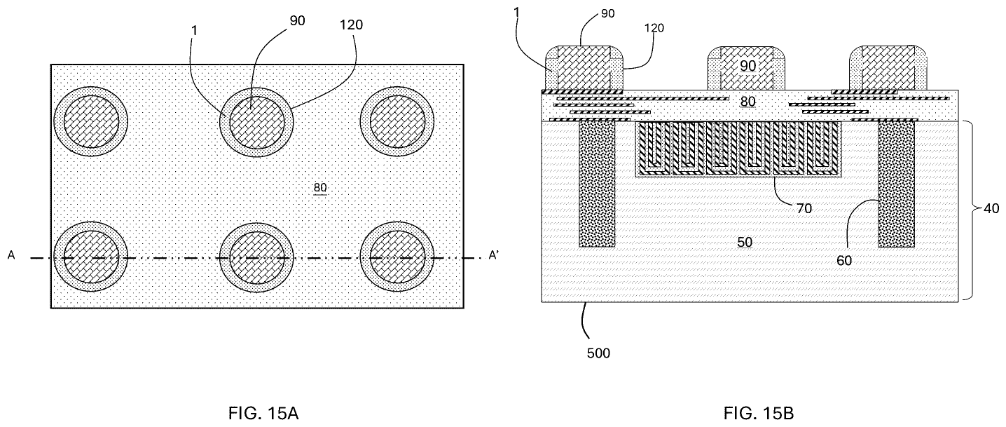

A detailed view of stripping grinding tape 5 and cleaning process is shown with the self-aligned spacer intermediate cladding structure 120 in FIGS. 15A and 15B. FIG. 15A shows a top-down view of the self-aligned spacer intermediate cladding structure 120, and FIG. 15B presents a vertical cross-sectional view along the plane A-A′ in FIG. 15A. These self-aligned spacer intermediate cladding structures 120 remain retained and intact during the grinding tape 5 attachment, detachment, and cleaning. For brevity, similar method steps that have been discussed above with respect to FIG. 8A and FIG. 8B may have a shortened description.

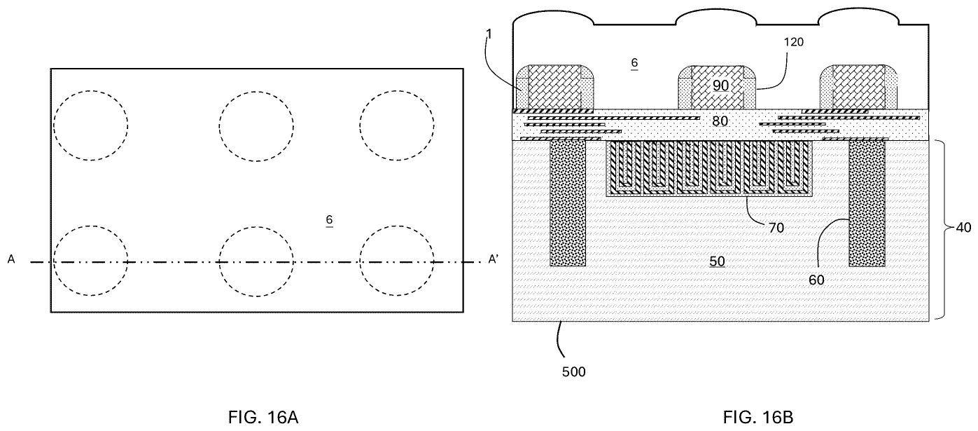

FIGS. 16A and 16B illustrate the application of a flowable oxide deposition or spin-coat dielectric 6 process onto the LSI 500. FIG. 16A shows a top view of the dielectric 6 on the LSI 500. FIG. 16B shows a cross-sectional view along line A-A′ of the self-aligned spacer intermediate cladding structure 120. After the tape detachment and cleaning processes as described in FIGS. 15A and 15B, a flowable oxide deposition or spin-coat dielectric 6 may be applied to cover the surface of the LSI 500. For brevity, similar method steps that have been discussed above with respect to FIG. 9 may have a shortened description.

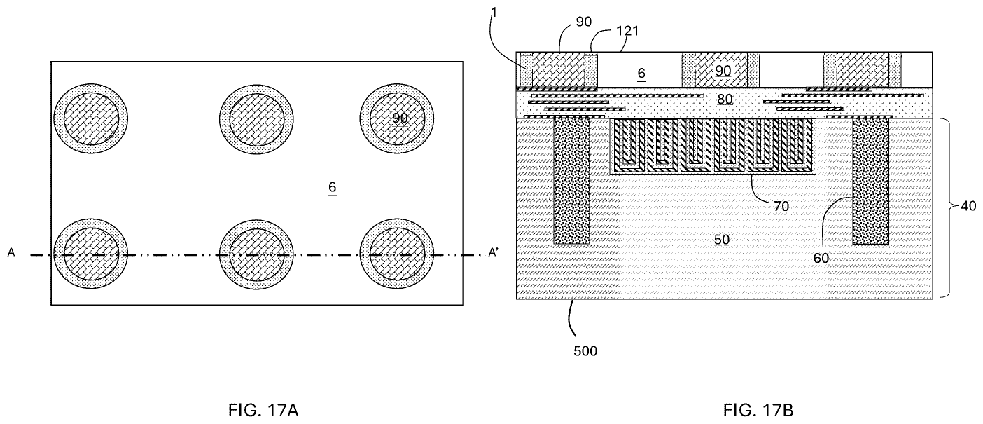

FIGS. 17A and 17B illustrate self-aligned spacer intermediate cladding structure 121 and depict the detailed view of forming and exposing self-aligned spacer intermediate cladding structure 121, which may include dielectric 6, ensuring the exposure of the top vias 90. FIG. 17A presents a top view of the structure after the exposure of the top vias 90 by chemical mechanical polishing (CMP) step S2A, and FIG. 17B shows a vertical cross-sectional view along line A-A′ in FIG. 17A.

Following flowable oxide deposition or spin-coat dielectric 6, Chemical Mechanical Planarization (CMP) step S2A is applied to remove portions of dielectric 6 and cladding layer, stopping on the top vias 90. The CMP step S2A is used to remove the excess portions of dielectric 6 and planarize the surface of dielectric 6. For brevity, similar method steps that have been discussed above with respect to FIG. 10 may have a shortened description.

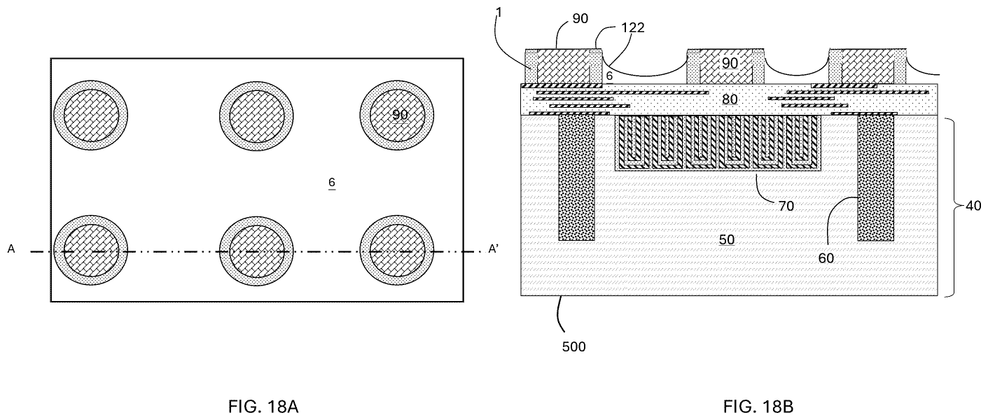

FIGS. 18A and 18B illustrate self-aligned spacer intermediate cladding structure 122 and depict the detailed view of forming and exposing self-aligned spacer intermediate cladding structure 122, which may include recessed dielectric 6, ensuring the exposure of the top vias 90. Following the chemical mechanical polishing (CMP) step S2A, an oxide etch back process S2B is carried out. The etch back step S2B involves the selective removal of portions of the spin-coat dielectric 6 to expose the self-aligned spacer intermediate cladding structure 122 that includes recessed dielectric 6. This may be achieved using a wet etch chemistry that selectively attacks the dielectric 6 but not the top vias 90. For brevity, similar method steps that have been discussed above with respect to FIG. 11 may have a shortened description.

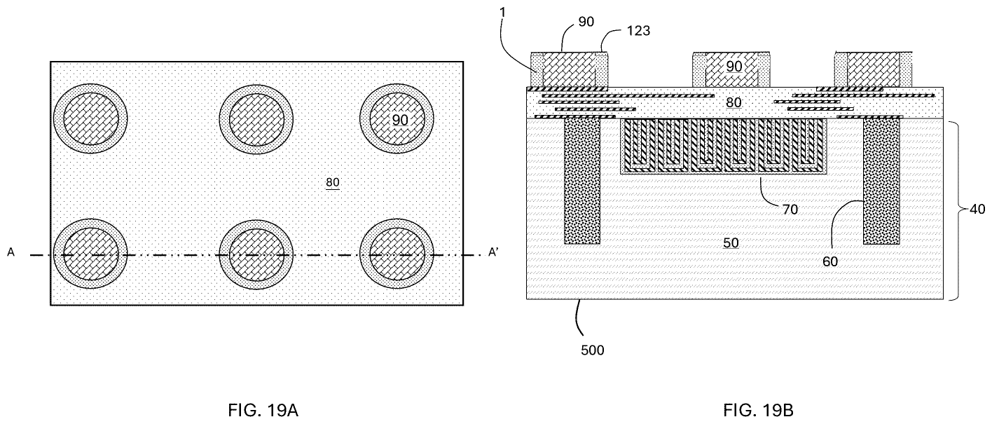

FIGS. 19A and 19B illustrate self-aligned spacer cladding structure 123 and depict the detailed view after the removal step S2C of dielectric 6 on the surface of RDL 80. Following step S2A, the etch back step S2C may be applied to achieve self-aligned spacer cladding structure 123, completely removing dielectric 6 on the surface of redistribution layer (RDL) 80 while exposing the top surface of the top vias 90, covering the sidewall of top vias 90 by the self-aligned spacer cladding structure 123, and not damaging RDL 80.

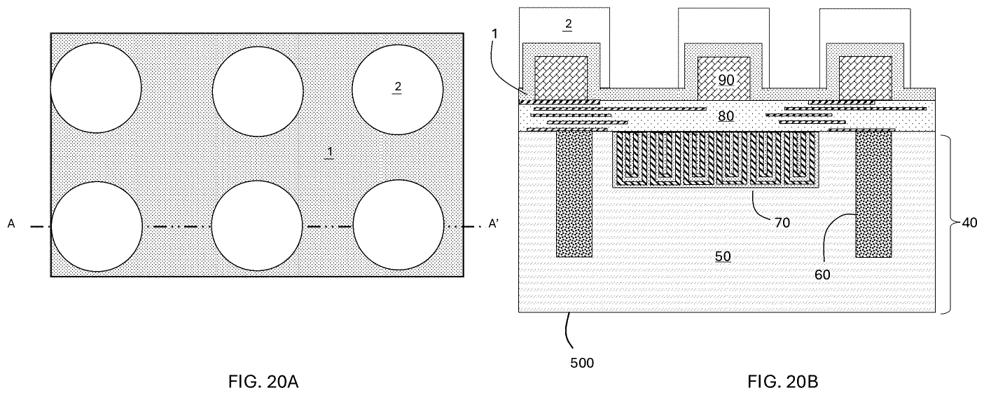

In another embodiment, following step S1, FIGS. 20A and 20B illustrate an intermediate stage of forming the tapered-foot intermediate cladding structure 130 and L-foot intermediate cladding structure 140. The photoresist 2 patterning process may be applied to the first embodiment intermediate blanket cladding layer 110 for step S3 and step S4. FIG. 20A provides a top-down view showing the distribution of vias, where photoresist 2 is patterned. FIG. 20B depicts a cross-sectional view along the line A-A′ in FIG. 20A, illustrating the structure after the photoresist is patterned to cover specific areas. In FIGS. 20A and 20B, a layer of photoresist 2 may be coated over the entire surface, followed by exposure to a light source through a mask to transfer the desired pattern. This step may include, but is not limited to, the use of positive or negative photoresist depending on the specific application requirements. The patterned photoresist serves as a mask for subsequent etching processes, protecting the underlying layers during material removal on the exposed area. In one embodiment, the photoresist may be developed to create openings that correspond to the vias, allowing for precise etching of the underlying oxide and metal layers, as shown in the FIG. 2. The patterned photoresist 2 ensures that only the exposed regions are etched away, while the protected areas remain intact. This photoresist patterning is a common step in the process flow, diverging into subsequent steps S3 and S4.

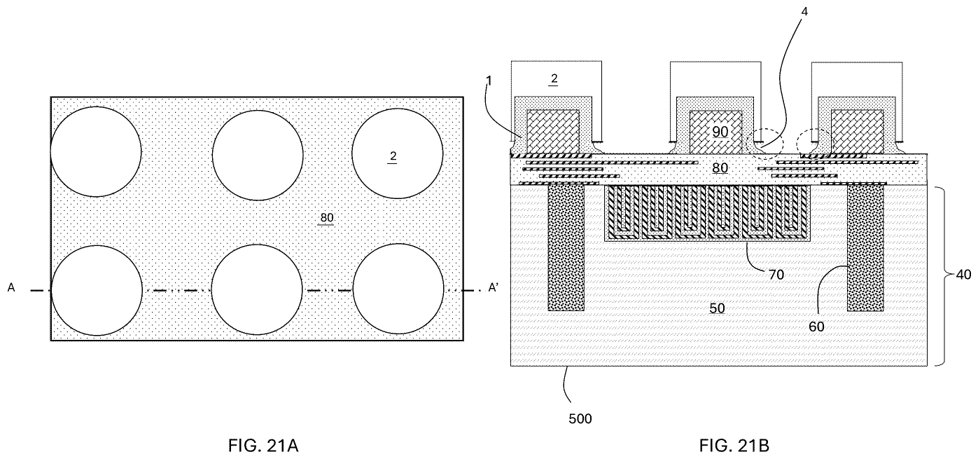

Referring to the step S3, FIGS. 21A and 21B illustrate the photoresist 2 patterning combined with a wet etch process, step S3, detailing the tapered-foot intermediate cladding structure formation around top vias 90. FIG. 21A provides a top-down view showing the elimination of a cladding layer on the surface of RDL 80 after the photoresist patterning step, while FIG. 21B depicts a cross-section view along the line A-A′ in FIG. 21A, illustrating the structure after the wet etch process. Following the photoresist patterning, a wet etch process, step S3 is used to etch the cladding material blanket layer of the first embodiment intermediate blanket layer cladding structure 110. The wet etch chemistry may include, but is not limited to, diluted hydrofluoric acid (DHF) or buffered oxide etch (BOE) for oxide materials and selective etchants for metal liners such as ammonium hydroxide (NH₄OH), hydrogen peroxide (H₂O₂), hydrogen sulfate (H₂SO₄) or hydrochloric acid (HCl). This wet chemical etching process results in the undercut profile 4 of the cladding layer(s) 1 beneath the patterned photoresist, creating the cladding structures around the top vias 90, as illustrated in FIG. 21B. The wet etch process may be carefully controlled to ensure precise material removal without damaging the underlying top vias 90 or the redistribution layer (RDL) 80, resulting in the desired tapered-foot intermediate cladding structure 130 after step S3.

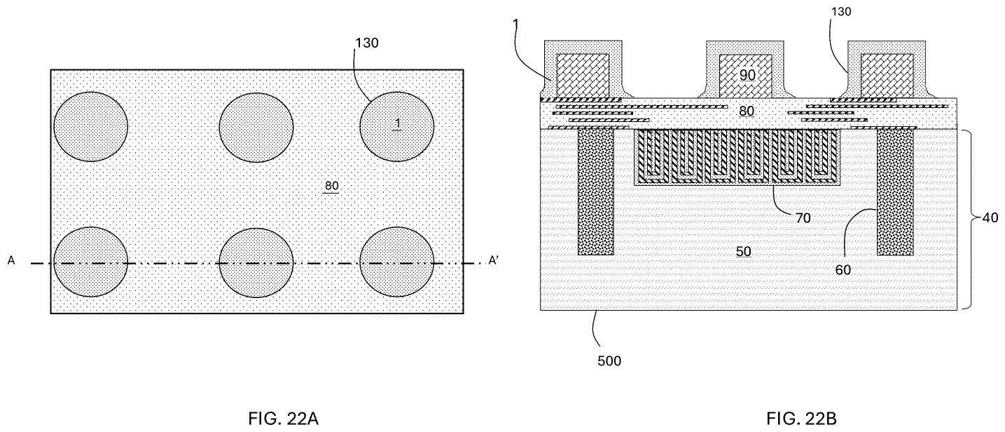

FIG. 22A provides a top-down view and the layout after the wet etch process, step S3 and photoresist strip. FIG. 22B depicts a vertical cross-sectional view along the line A-A′ in FIG. 22A, illustrating the desired tapered-foot intermediate cladding structure 130 after the photoresist 2 has been stripped away. The structure in FIG. 22B highlights the elimination of the cladding layer from the surfaces of RDL 80, ensuring that surfaces are exposed and free from any residual materials.

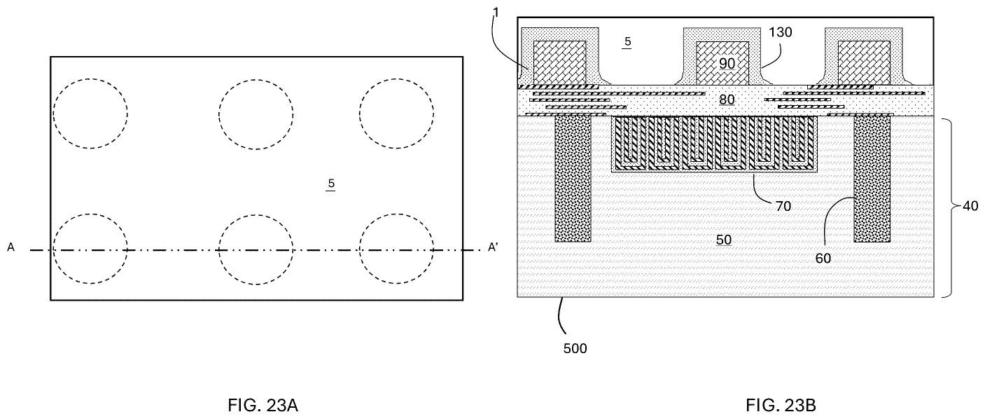

A detailed view of the grinding tape 5 attachment is shown with the tapered-foot intermediate cladding structure 130 in FIGS. 23A and 23B. FIG. 23A shows a top-down view of the tapered-foot intermediate cladding structure 130, and FIG. 23B presents a vertical cross-sectional view along the plane A-A′ in FIG. 23A. This process of the grinding tape 5 attachment provides mechanical support and protection to the delicate structures of the LSI die during subsequent grinding processes, covering the top vias 90 and other exposed elements. For brevity, similar method steps that have been discussed above with respect to FIG. 7 may have a shortened description.

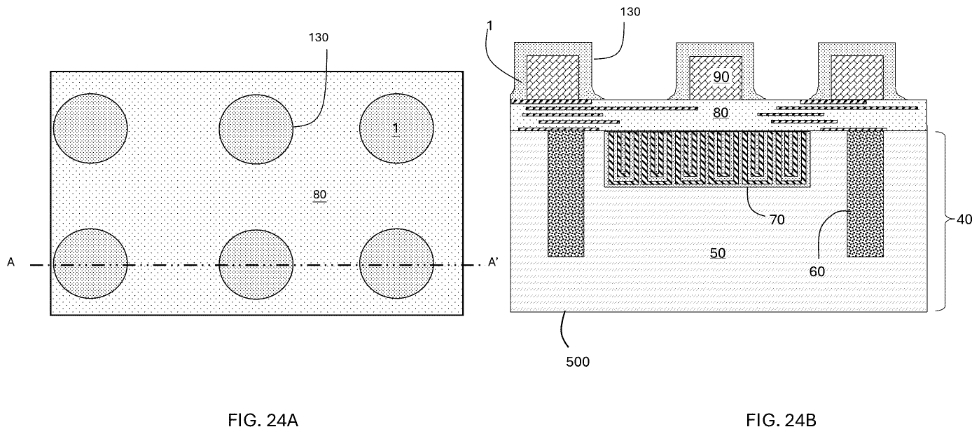

A detailed view of stripping grinding tape 5 and cleaning process is shown with the tapered-foot intermediate cladding structures 130 in FIGS. 24A and 24B. FIG. 24A shows a top-down view of the tapered-foot intermediate cladding structure 130, and FIG. 24B presents a vertical cross-sectional view along the plane A-A′ in FIG. 24A. These tapered-foot intermediate cladding structures 130 remain intact during the grinding tape 5 attachment, detachment, and cleaning. For brevity, similar method steps that have been discussed above with respect to FIG. 8 may have a shortened description.

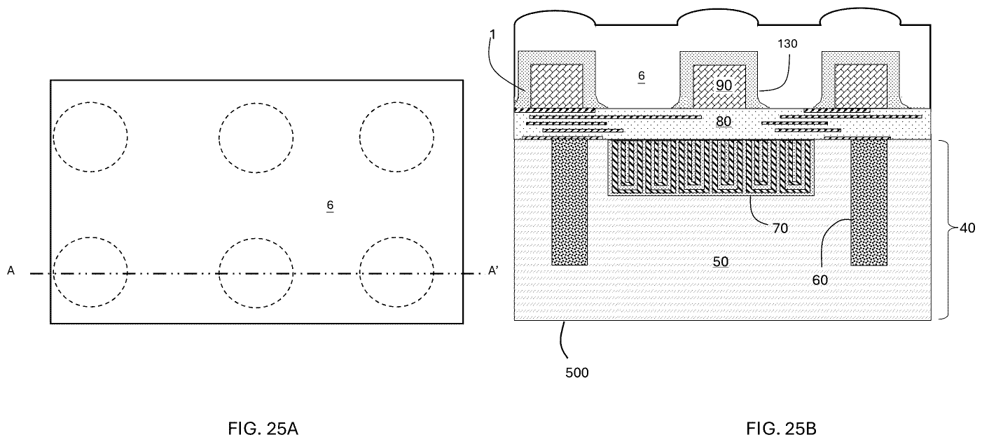

FIGS. 25A and 25B illustrate the application of a flowable oxide deposition or spin-coat dielectric 6 process onto the LSI 500. FIG. 25A shows a top view of each tapered-foot intermediate cladding structure 130. FIG. 25B shows a cross-sectional view along line A-A′ of each tapered-foot intermediate cladding structure 130. After the tape detachment and cleaning processes as described in FIGS. 24A and 24B, a flowable oxide deposition or spin-coat dielectric 6 may be applied to cover the surface of the LSI 500. For brevity, similar method steps that have been discussed above with respect to FIG. 9 may have a shortened description.

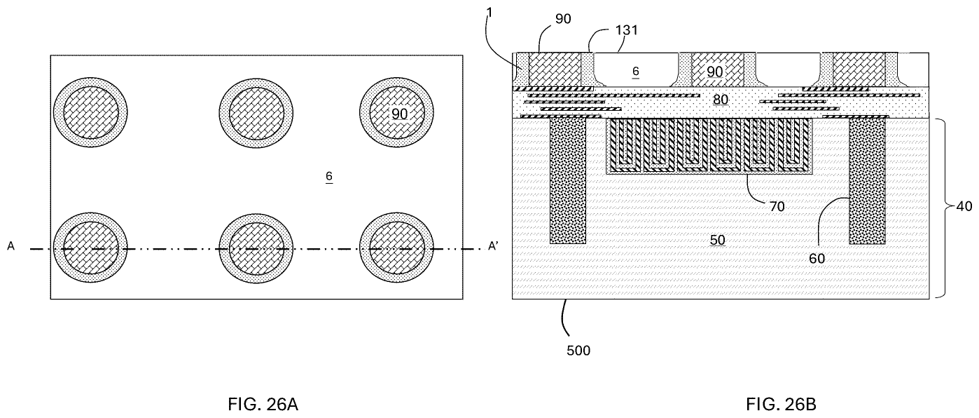

FIGS. 26A and 26B illustrate tapered-foot intermediate cladding structure 131 and depict the detailed view of forming and exposing the tapered-foot intermediate cladding structure 131, which may include dielectric 6, ensuring the exposure of the top vias 90. FIG. 26A presents a top view of the structure after the exposure of the top vias 90 by chemical mechanical polishing (CMP) S3A, and FIG. 26B shows a vertical cross-sectional view along line A-A′ in FIG. 26A. Following flowable oxide deposition or spin-coat dielectric 6, Chemical Mechanical Polishing (CMP) step S3A is applied to remove dielectric 6 and cladding layer, stopping on the top vias 90. The CMP step S3A is used to remove the excess dielectric 6 and planarize the surface of dielectric 6. For brevity, similar method steps that have been discussed above with respect to FIG. 10 may have a shortened description.

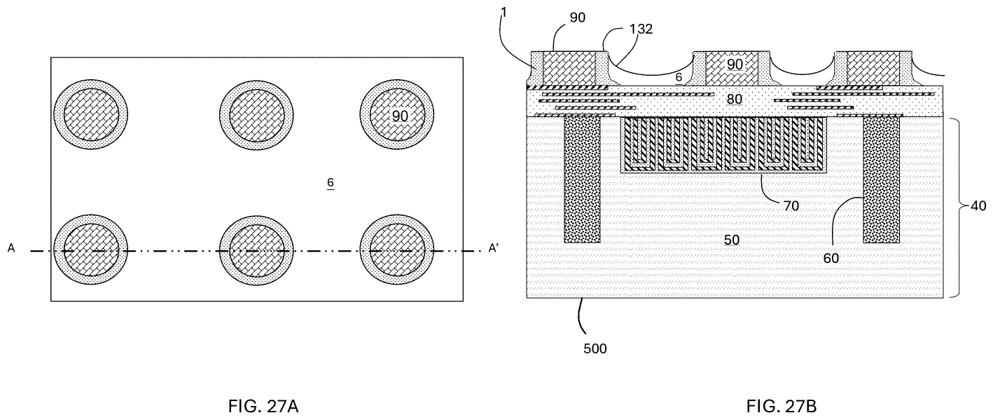

FIGS. 27A and 27B illustrate a tapered-foot intermediate cladding structure 132 and depict the detailed view of forming and exposing a tapered-foot intermediate cladding structure 132 in conjunction with recessed dielectric 6, ensuring the exposure of the top vias 90. Following the chemical mechanical polishing (CMP) step S3A, an oxide etch back step S3B is carried out. The etch back step S3B involves the selective removal of the spin-coat dielectric 6 to expose the tapered-foot intermediate cladding structure 132, which may include recessed dielectric 6. This may be achieved using a wet etch chemistry that selectively attacks the dielectric 6 but not the top vias 90. For brevity, similar method steps that have been discussed above with respect to FIG. 11 may have a shortened description.

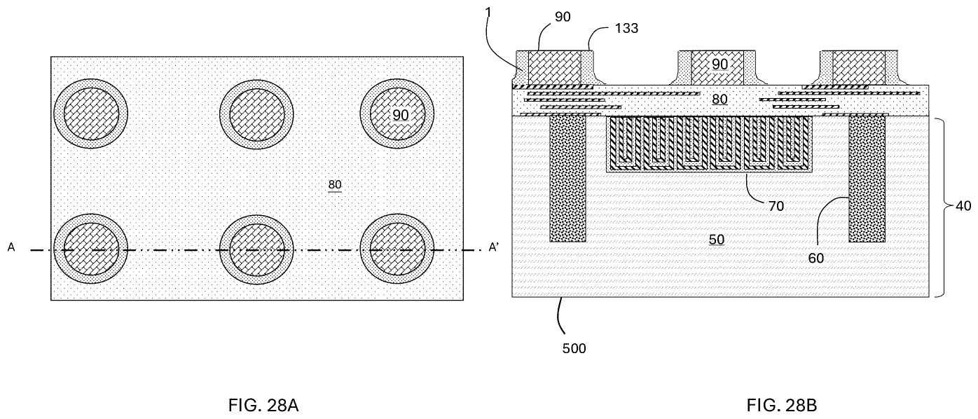

FIGS. 28A and 28B illustrate a tapered-foot cladding structure 133 and depict the detailed view after the complete removal step S3C of a dielectric 6 on the surface of RDL 80. Following step S3A, the complete etch back step S3C may be applied to achieve a tapered-foot cladding structure 133, removing dielectric 6 on the surface of redistribution layer (RDL) 80 while exposing the top surface of the top vias 90, covering the sidewall of top vias 90 by the cladding layer(s) 1, and not damaging RDL 80.

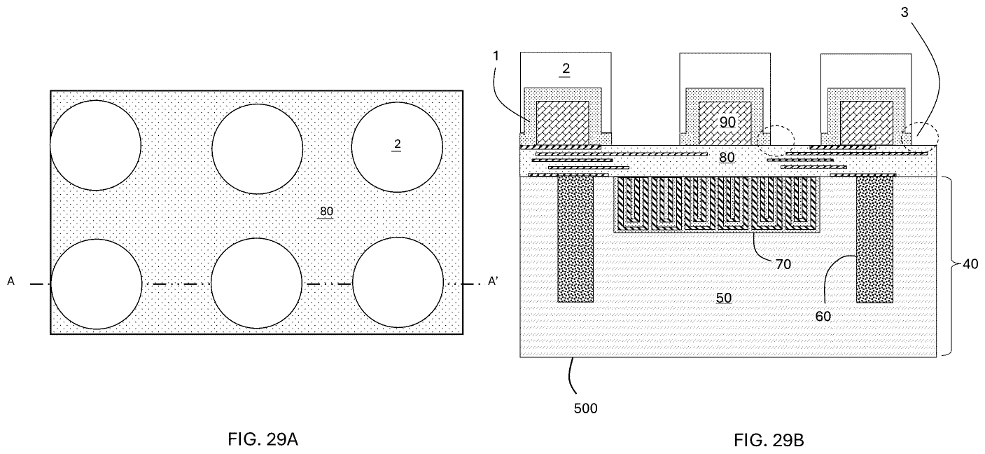

In a fourth embodiment cladding structure, as described in FIGS. 20A and 20B, the photoresist 2 patterning is an intermediate stage to form a L-foot intermediate cladding structure 140. Referring to the step S4, FIGS. 29A and 29B depict the photoresist 2 patterning combined with a dry etch step S4, illustrating the precision required to achieve well-defined features. FIG. 29A offers a top view after the photoresist 2 has been patterned, while FIG. 29B provides a vertical cross-sectional view along the line A-A′ in FIG. 29A, illustrating the results of the dry etch process. The etch chemistry for this process may involve, but is not limited to, fluorocarbon-based gases such as CF₄, CHF₃, or C₄F₈, which selectively etch the oxide materials while stopping on the underlying metal liners. A different etch chemistry may be employed to etch the metal liners, such as Ti, TiN, Ta, TaN, TaC, TiC, TaCN, TiCN, or MoN. Chlorine-based or bromine-based gases, such as Cl₂, BC₁₃, or HBr, are commonly used for their effectiveness in etching metal materials, and the etch process is carefully controlled to stop on the surface of the RDL 80, preventing damage to the underlying layers. In this embodiment, the dry etch is used to cut through the oxide and metal liner layers precisely, ensuring a clean, vertical cut profile 3 of the L-foot intermediate cladding structure 140. The use of anisotropic etching step S4 allows for highly directional material removal, resulting in the formation of square ends on the L-foot intermediate cladding structures 140. This process ensures that the vertical sidewalls remain intact and that the etching does not undercut the photoresist mask. By carefully controlling the etch chemistry and parameters, such as gas composition and plasma power, the etch rate can be finely tuned to achieve the desired profile without damaging the top vias 90 and RDL 80 in the local silicon interposer 500. After the dry etch process, selective chemical wet cleaning may be performed to remove any residual etch by-products and to ensure the cleanliness of the surface.

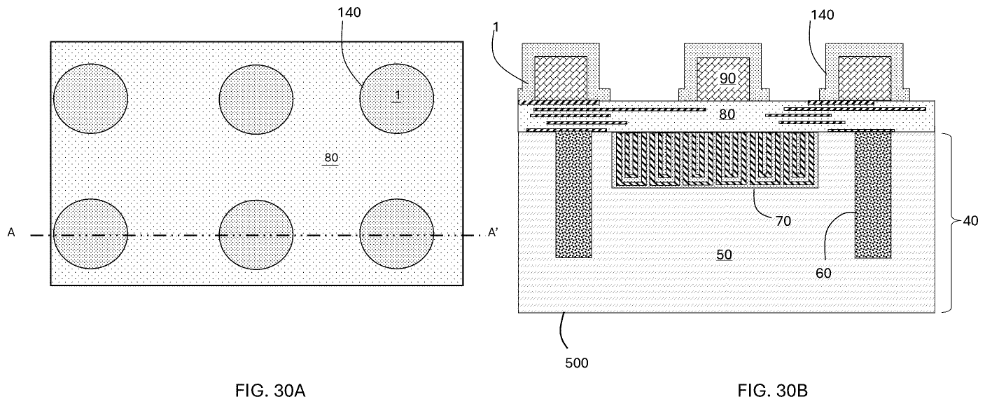

FIGS. 30A and 30B illustrate the process of stripping patterned photoresist.

The clean removal of the photoresist 2 may involve, but is not limited to, the use of wet chemical stripping agents or plasma ashing to remove the residual photoresist 2 completely. FIG. 30A provides a top-down view after stripping off the photoresist, exposing the L-foot intermediate cladding structures 140 and the top surface of the redistribution layer (RDL) 80. FIG. 30B offers a vertical cross-sectional view along the A-A′ in FIG. 30A, detailing the results after the photoresist is stripped away and revealing L-foot intermediate cladding structure 140 surrounding top vias 90.

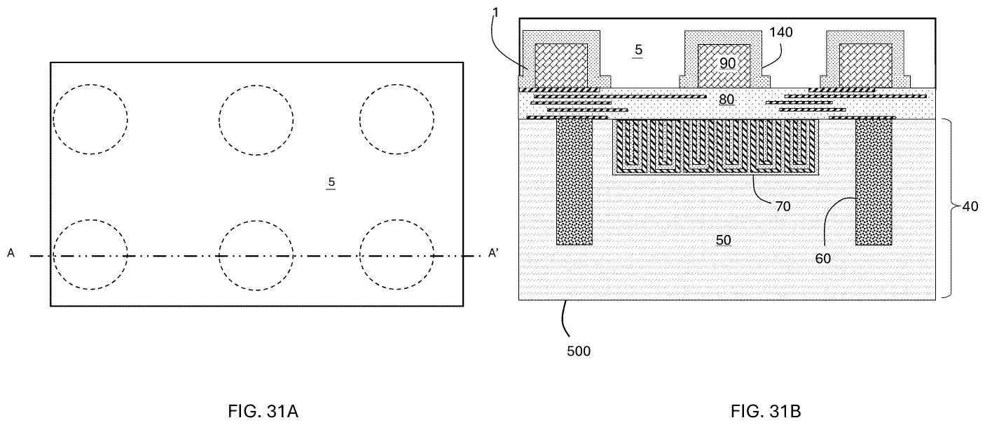

A detailed view of the grinding tape 5 attachment is shown with the L-foot intermediate cladding structure 140 in FIGS. 31A and 31B. FIG. 31A shows a top-down view of the L-foot intermediate cladding structure 140, and FIG. 31B presents a vertical cross-sectional view along the plane A-A′ in FIG. 31A. This process of the grinding tape 5 attachment provides mechanical support and protection to the delicate structures of the LSI die during subsequent grinding processes, covering the top vias 90 and other exposed elements. For brevity, similar method steps that have been discussed above with respect to FIG. 7 may have a shortened description.

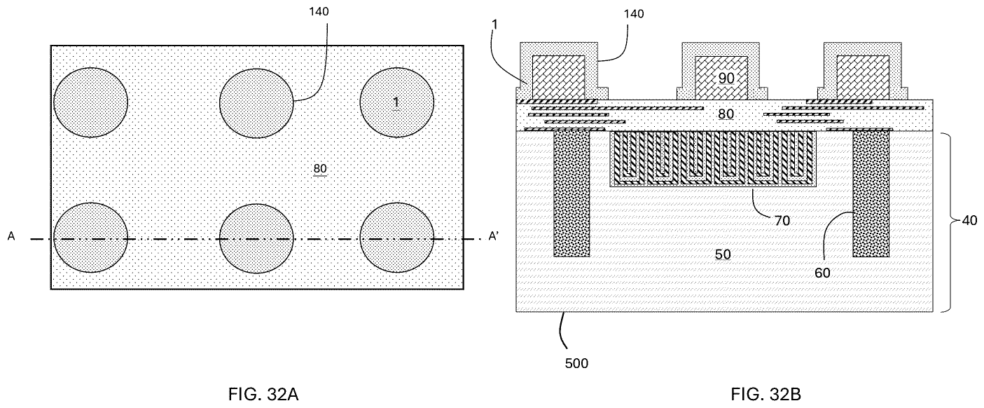

A detailed view of stripping grinding tape 5 and cleaning process is shown with the L-foot intermediate cladding structures 140 in FIGS. 32A and 32B. FIG. 32A shows a top-down view of the L-foot intermediate cladding structure 140, and FIG. 32B presents a vertical cross-sectional view along the plane A-A′ in FIG. 32A. The L-foot intermediate cladding structure 140 remains intact during the grinding tape 5 attachment, detachment, and cleaning. For brevity, similar method steps that have been discussed above with respect to FIG. 8 may have a shortened description.

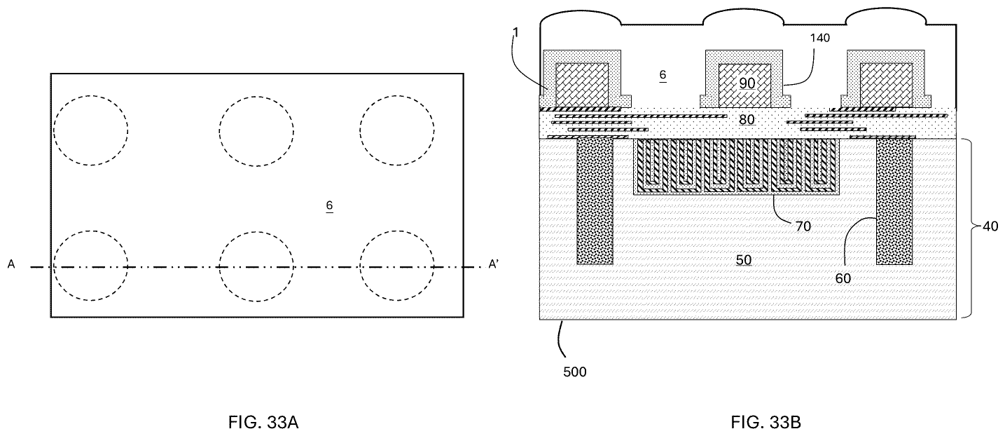

FIGS. 33A and 33B illustrate the application of a flowable oxide deposition or spin-coat dielectric 6 process onto the LSI 500. FIG. 33A shows a top view of each L-foot intermediate cladding structure 140. FIG. 33B shows a cross-sectional view along line A-A′ of each L-foot intermediate cladding structure 140. After the tape detachment and cleaning processes as described in FIGS. 32A and 32B, a flowable oxide deposition or spin-coat dielectric 6 may be applied to cover the surface of the LSI 500. For brevity, similar method steps that have been discussed above with respect to FIG. 9 may have a shortened description.

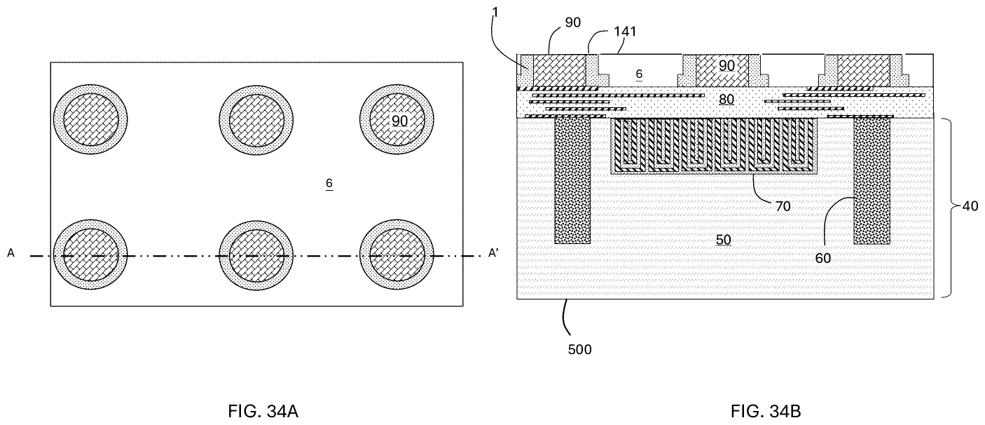

FIGS. 34A and 34B illustrate a L-foot intermediate cladding structure 141 and depict the detailed view of forming and exposing a L-foot intermediate cladding structure 141 in conjunction with dielectric 6, ensuring the exposure of the top vias 90. FIG. 34A presents a top view of the structure after the exposure of the top vias 90 by chemical mechanical polishing (CMP) step S4A, and FIG. 34B shows a vertical cross-sectional view along line A-A′ in FIG. 34A. Following flowable oxide deposition or spin-coat dielectric 6, Chemical Mechanical Polishing (CMP) step S4A is applied to remove portions of dielectric 6 and the cladding layer, stopping on the top vias 90. The CMP step S4A removes the excess dielectric 6 and planarizes the surface of a dielectric 6. For brevity, similar method steps that have been discussed above with respect to FIG. 10 may have a shortened description.

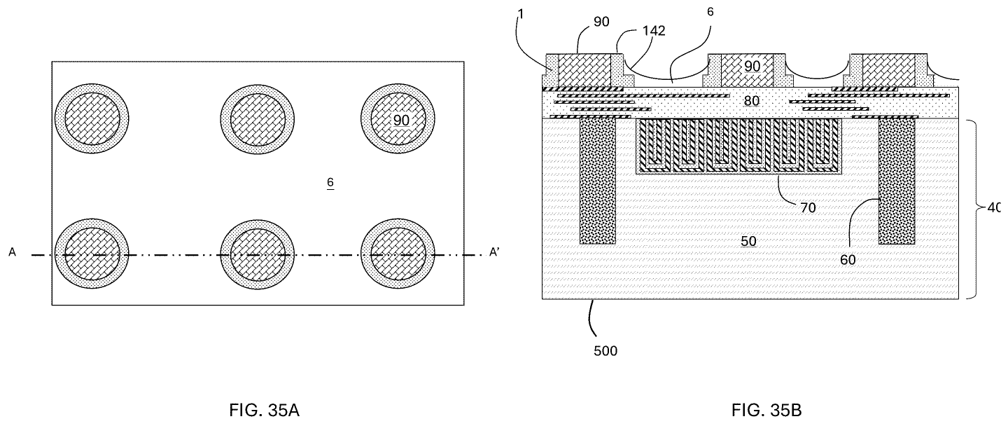

FIGS. 35A and 35B illustrate a L-foot intermediate cladding structure 142 and depict the detailed view of forming and exposing a L-foot intermediate cladding structure 142 in conjunction with recessed dielectric 6, ensuring the exposure of the top vias 90. Following the chemical mechanical polishing (CMP) step S4A, an oxide etch back step S4B is carried out. The etch back step S4B involves the selective removal of the spin-coat dielectric 6 to expose the L-foot intermediate cladding structure 142 in conjunction with recessed dielectric 6. This may be achieved using a wet etch chemistry that selectively attacks the dielectric 6 but not the top vias 90. For brevity, similar method steps that have been discussed above with respect to FIG. 11 may have a shortened description.

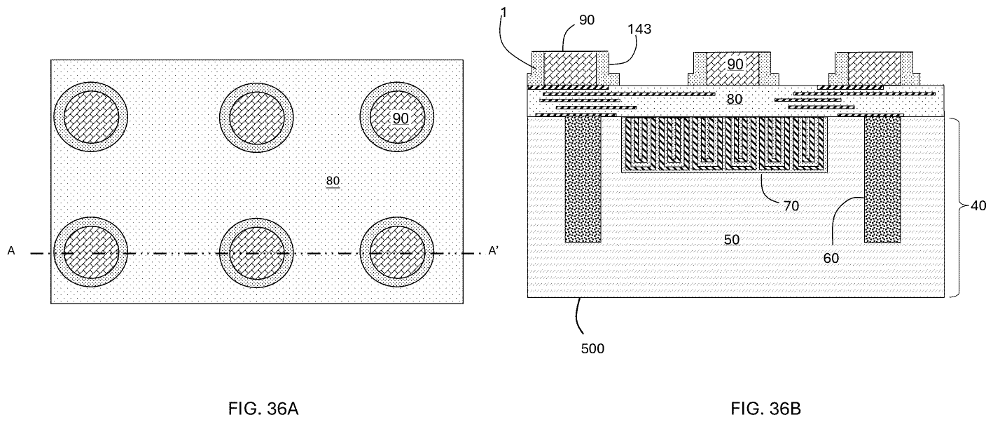

FIGS. 36A and 36B illustrate a L-foot cladding structure 143 and depict the detailed view after the complete removal step S4C of a dielectric 6 on the surface of RDL 80. Following S4A, the complete etch back process S4C may be applied to achieve L-foot cladding structure 143, completely removing dielectric 6 on the surface of redistribution layer (RDL) 80 while exposing the top surface of the top vias 90, covering the sidewall of top vias 90 by the cladding layer, and not damaging RDL 80.

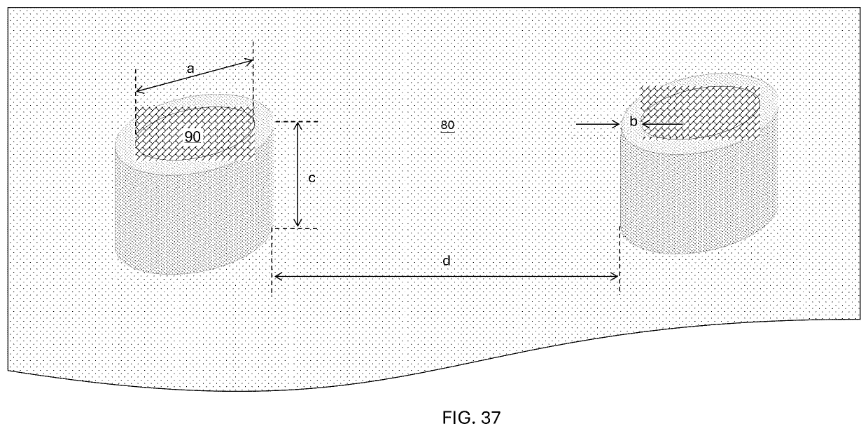

FIG. 37 depicts the common dimension of cladding structures. The diameter of the top via ‘a’ may be, but is not limited to, in the range of 1 um to 100 um. The thickness of cladding layer ‘b’ may be, but is not limited to, thicker than 100 nm. The distance between top vias may be, but is not limited to, in the range of 1 um to 500 um. The height of the top via ‘c’ may be, but is not limited to, in the range of 1 um to 100 um.

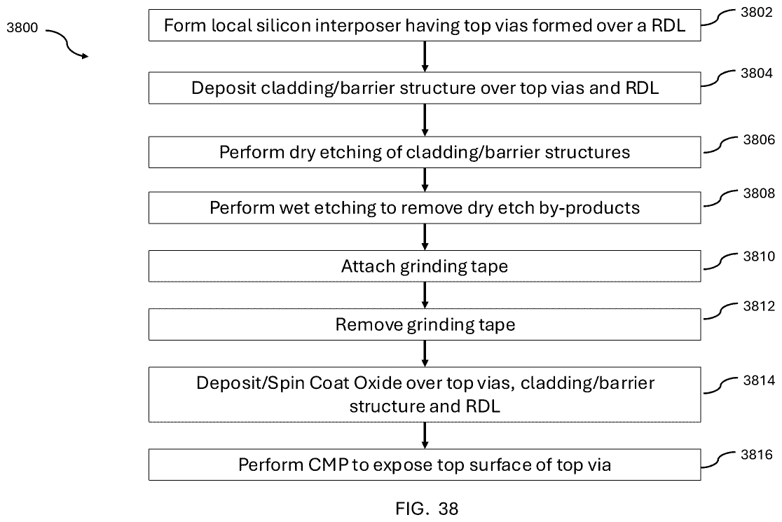

FIG. 38 is a process flowchart that illustrates the method steps to form a local silicon interposer with top vias that have a barrier structure that protects and mitigates against damage to the top vias during a grinding process. With reference to FIG. 2 (step S2), 3 (step S2A), 13A-17B, and 38, method 3800 is illustrated. With reference to FIGS. 1A, 1B, 2 (step S0) and 38, in step 3802, a local silicon interposer 500 may be formed. As discussed above with reference to FIGS. 1A, 1B and 2 (step S0), the LSI 500 may be formed to include any and/or all of TSVs 60 formed in a silicon substrate 40, a deep trench capacitor 70, a RDL 80, and top vias 90.

With reference to FIGS. 2(step S1), 6A, 6B, and 38, in step 3804, cladding layers may be deposited over the top vias 90 and RDL 80 to form first embodiment intermediate blanket layer cladding structure 110. The cladding material blanket layer may comprise any combination of various metal liners such as CuOx on the top via surface, Ta, Ti, TaN, TIN, TiC, TaC, TiCN, TaCN, Mo, or MON, followed by oxide layers. This cladding material blanket layer may include, but is not limited to, SiOCHx, SiOx, SiNx, and SiON, with “x” ranging from 0.1 to less than 1. The thickness of these layers may vary depending on the specific application, and the sequence in which they are deposited may also differ.

With reference to FIGS. 2(step S2), 13A, 13B, and 38, in step 3806, a dry etching process may be performed to etch the first embodiment intermediate blanket layer cladding structure 110 to form a self-aligned spacer cladding structure 120 that include top vias 90 with cladding materials remaining on the sidewalls of the top vias 90. In step 3808, a wet etch process may be performed to remove and dry etch to remove any residual etch by-products and ensure the surface's cleanliness.

With reference to FIGS. 14A, 14B, and 38, in step 3810, grinding tape 5 may be attached to the top vias with self-aligned spacer cladding structures 120. A grinding process may be performed. In step 3812, the grinding tape 5 may be removed from the self-aligned spacer cladding structure 120 following the grinding process.

With reference to FIGS. 16A, 16B, and 38, in step 3814, a flowable dielectric 6 may be deposited or spin-coated over the top vias 90 with self-aligned spacer cladding structures 120 and RDL 80. With reference to FIGS. 17A, 17B, and 38, in step 3816, a CMP process may be performed to remove excess material from the top via 90, cladding material, and flowable dielectric 6 such that a top surface of each of the top via 90, cladding material, and flowable dielectric 6 are co-planar. In subsequent processing steps, various amounts of the flowable dielectric 6 may be removed.

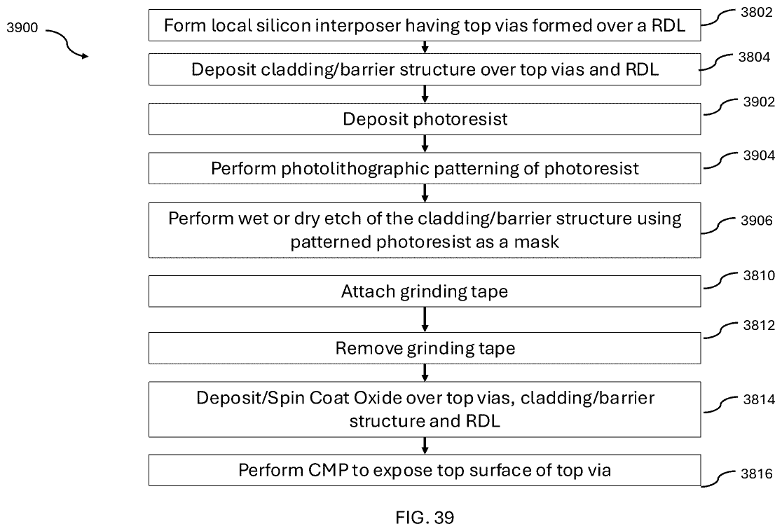

FIG. 39 is a process flowchart that illustrates the method steps to form a local silicon interposer with top vias that have a barrier structure that protects and mitigate against damage to the top vias during a grinding process. With reference to FIG. 2 (steps S3, S4), 3 (steps S3A, S4A), 20A-36B, and 39, a method 3900 is illustrated. For brevity, similar method steps that have been discussed above with respect to FIG. 38 may have a shortened description. With reference to FIGS. 1A, 1B, 2 (step S0) and 38, in step 3802, a local silicon interposer 500 may be formed. With reference to FIG. 2 (step S1), 6A, 6B, and 38, in step 3804, a cladding material blanket layer may be deposited over the top vias 90 and RDL 80 to form first embodiment intermediate blanket layer cladding structure 110. With reference to FIG. 2 (steps S3, S4), 20A, 20B, and 39, in step 3902, a photoresist layer 2 may be coated over the top vias 90 with first embodiment intermediate blanket layer cladding structure 110. In step 3904, using a photolithographic process, a pattern may be transferred to the photoresist layer 2.

In some embodiments, with reference to FIGS. 20A-22B, in step 3906, a wet etch process may be performed to remove portions of the cladding materials. The wet etch chemistry may include, but is not limited to, diluted hydrofluoric acid (DHF) or buffered oxide etch (BOE) for oxide materials and any combination of selective etchants for metal liners such as ammonium hydroxide (NH₄OH), hydrogen peroxide (H₂O₂), hydrogen sulfate (H₂SO₄) or hydrochloric acid (HCl). This wet chemical etching process results in the undercut profile 4 of the cladding layer beneath the patterned photoresist 2, creating the cladding structures around the top vias 90, as illustrated in FIG. 21B. The wet etch process may be carefully controlled to ensure precise material removal without damaging the underlying top vias 90 or the redistribution layer (RDL) 80, resulting in the desired tapered-foot intermediate cladding structure 130 after step S3.

In other embodiments, with reference to FIGS. 29A-30B, in step 3906, a dry etch process may be performed to remove portions of the cladding materials. The etch chemistry for this dry-etch process may involve, but is not limited to, fluorocarbon-based gases such as CF₄, CHF₃, or C₄F₈, which selectively etch the oxide materials while stopping on the underlying metal liners. A different etch chemistry may be used to etch the metal liners, such as Ti, TiN, Ta, TaN, TaC, TiC, TaCN, TiCN, or MoN. Chlorine-based or bromine-based gases, such as Cl₂, BCl₃, or HBr, are commonly used for their effectiveness in etching metal materials, and the etch process is carefully controlled to stop on the surface of the RDL 80, preventing damage to the underlying layers. In this embodiment, the dry etch is used to cut through the oxide and metal liner layers precisely, ensuring a clean, vertical cut profile 3 of the L-foot intermediate cladding structure 140. The use of anisotropic etching step S4 allows for highly directional material removal, resulting in the formation of square ends on the L-foot intermediate cladding structures 140. This process ensures that the vertical sidewalls remain intact and that the etching does not undercut the photoresist mask. By carefully controlling the etch chemistry and parameters, such as gas composition and plasma power, the etch rate can be finely tuned to achieve the desired profile without damaging the underlying vias 90 and RDL 80 in the local silicon interposer 500. After the dry etch process, selective chemical wet cleaning may be performed to remove any residual etch by-products and to ensure the cleanliness of the surface.

Once the tapered-foot intermediate cladding structure 130 or L-foot intermediate cladding structure 140 are formed using either the wet etch or dry etch process, the steps 3810-3816 may be performed as discussed above.

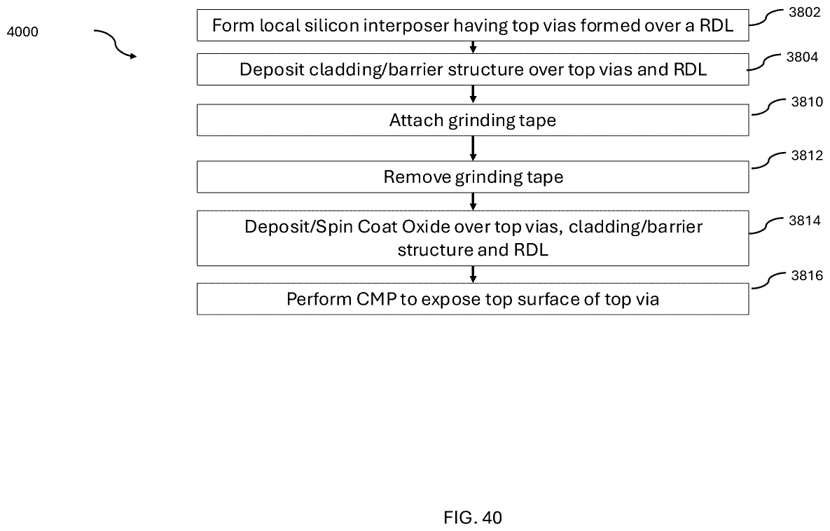

FIG. 40 is a process flowchart that illustrates the method steps to form a local silicon interposer with top vias that have an embodiment cladding structure (113, 123, 133, 143) that protect and mitigate against damage to the top vias 90 during a grinding process. With reference to FIG. 2 (step S1), 3 (step S1A), 6A-10B, and 40, method 4000 is illustrated. For brevity, similar method steps that have been discussed above with respect to FIG. 38 may have a shortened description. With reference to FIGS. 1A, 1B, 2 (step S0) and 38, in step 3802, a local silicon interposer 500 may be formed. With reference to FIG. 2 (step S1), 6A, 6B, and 38, in step 3804, a cladding material blanket layer may be deposited over the top vias 90 and RDL 80 to form first embodiment intermediate blanket layer cladding structure 110. The conformal cladding layer covers the top vias 90 and the surface of RDL 80, resulting in the formation of first embodiment intermediate blanket layer cladding structure 110.

Once the first embodiment intermediate blanket layer cladding structure 110 is formed using conformal cladding layer, the steps 3810-3816 may be performed as discussed above.

According to various embodiments of the present disclosure, the via cladding structures for local silicon interposer (LSI) die are beneficial for electrical performance and reliability in semiconductor package technology. The via barrier structures address the reliability failure issues such as metallic wire growth, metal loss, and tape residue reactions by ensuring that the cladding structures enhance the electrical performance, reliability, and long-term stability in the semiconductor package devices. The adaptable method of forming cladding structures may meet diverse design requirements, making it suitable for various high-performance applications, including high-performance computing (HPC) and artificial intelligence (AI).

Referring to all drawings and according to various embodiments of the present disclosure, a local silicon interposer 500 having top via with embodiment cladding structures (113, 123, 133, 143) may be provided. The local silicon interposer 500 may include a top via 90 formed over a redistribution layer (RDL) 80, and a conformal cladding layer formed over the sidewalls of the top via 90, wherein the conformal cladding layer provides a barrier between the sidewall of top vias 90 and chemically reacting materials, residues and contamination sources, forming self-aligned spacer cladding structures (121, 122, and 123), tapered-foot cladding structures (131, 132, and 133), and L-foot cladding structures (141, 142, and 143). Alternatively, the local silicon interposer 500 may include via cladding structures comprising multiple layers of oxide, wherein a cladding material blanket layer encapsulates all surfaces of the sidewall of top vias 90 and the redistribution layer 80 (RDL) over a substrate 40, forming blanket layer cladding structures (111,112, and 113). The top via's top surface is exposed, such that another continuation of interconnection is further enabled.

In one embodiment, the conformal cladding layer may comprise multiple layers of oxides, such as SiOCH, SiOx, SiON, SiNx, or CuOx. In another embodiment, the conformal cladding layer may comprise a metal liner, such as Ta, Ti, TaN, TiN, Mo, MoN, TaC, TiC, TaCN, or TiCN. In one embodiment, the conformal cladding structure includes a self-aligned spacer cladding structure 123. In one embodiment, the self-aligned spacer cladding structure 123 may be formed on the sidewall of a top via 90. In one embodiment, the conformal cladding structure may include a tapered-foot cladding structure 130. In one embodiment, the tapered-foot cladding structure 130 may be formed on the sidewall of a top via 90. In one embodiment, the conformal cladding structure ma include a L-foot cladding structure 140. In one embodiment, the L-foot cladding structure 140 may be formed on the sidewall of a top via 90. In one embodiment, the conformal cladding structure is formed on the sidewall of a top via 90, extending continuously over a redistribution layer (RDL) 80.

According to another aspect of the present disclosure, a method of forming a local silicon interposer 500 is provided, which comprises depositing at least one of a conformal cladding material blanket layer and a metal liner on the top surface of a top via 90 and the redistribution layer (RDL) 80 to form an intermediate blanket layer cladding structure (110), and etching the intermediate blanket layer cladding structure (110) over the redistribution layer (RDL) 80.

In one embodiment, the method for forming a local silicon interposer 500 may comprise etching the intermediate blanket layer cladding structure (110), wherein a wet etch, isotropic etch, or anisotropic etch may be chosen to remove the cladding material blanket layer in unmasked area of photolithographic patterns, such that the cladding material blanket layer over the sidewall of a top via 90 remains intact. In one embodiment, the etching comprises an anisotropic etch, such that the cladding material blanket layer over the sidewall of a top via 90 remains intact. In another embodiment, the etching comprises a wet etch or isotropic etch in an unmasked area of photolithographic patterns, such that the cladding material blanket layer over the sidewall of a top via 90 remains intact. In another embodiment, the etching comprises an anisotropic directional etch in an unmasked area of photolithographic patterns, such that the cladding material blanket layer over the sidewall of a top via 90 remains intact. In another embodiment, the deposition of the at least one of the conformal cladding material and the metal liner comprises depositing the conformal cladding material blanket layer over the top surface of a top via 90 and a redistribution layer (RDL) 80, wherein the conformal cladding material blanket layer is in contact with a top via 90 and the surface of a redistribution layer (RDL) 80.

According to another aspect of the present disclosure, a method for forming a via cladding structure is provided, which may include depositing at least one of a conformal oxide and a metal liner over the top surface of a top via and a redistribution layer (RDL) to form a cladding layer; depositing a flowable or spin-coat dielectric 6 over the cladding material blanket layer and a redistribution layer (RDL) 80, and removing the dielectric 6 and the cladding material blanket layer over the surface of a top via to expose the top surface of a top via 90.

In one embodiment, wherein removing the dielectric 6 and the cladding layer over the top surface of the top via 90 comprise the removing the dielectric 6 by etch back, where a coverage of a sidewall of the top via 90 by cladding material blanket layer is more than 70%.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A via cladding structure, comprising:
a top via formed over a redistribution layer; and
a conformal cladding material blanket layer formed over the sidewalls of the top via, wherein a top surface of the top via is exposed such that another interconnection is formed on the top surface of the top via.

2. The via cladding structure of claim 1, wherein the conformal cladding material blanket layer comprises multiple layers of oxides.

3. The via cladding structure of claim 2, further comprising a metal liner.

4. The via cladding structure of claim 2, wherein the multiple layers of oxide comprise at least one of SiOCH, SiOx, SiON, SiNx, or CuOx.

5. The via cladding structure of claim 3, wherein the metal liners comprise at least one of Ta, Ti, TaN, TiN, Mo, MON, TaC, TiC, TaCN, or TiCN.

6. The via cladding structure of claim 1, wherein the via cladding structure is formed as a self-aligned spacer cladding structure.

7. The via cladding structure of claim 6, wherein the self-aligned spacer cladding structure is formed on the sidewall of a top via.

8. The via cladding structure of claim 1, wherein the via cladding structure is formed as a tapered-foot cladding structure.

9. The via cladding structure of claim 8, wherein the tapered-foot cladding structure is formed on the sidewall of a top via.

10. The via cladding structure of claim 1, wherein the via cladding structure is formed as a L-foot cladding structure.

11. The via cladding structure of claim 10, wherein the L-foot cladding structure is formed on the sidewall of a top via.

12. The via cladding structure of claim 1, wherein the via cladding structure is formed as a blanket layer cladding structure.

13. The via cladding structure of claim 12, wherein the blanket layer cladding structure is formed on the sidewall of a top via, extending continuously over a redistribution layer (RDL).

14. A method of forming a via cladding structure comprising:
depositing at least one of a conformal oxide and a metal liner over the top surface of a top via and a redistribution layer (RDL) to form a cladding material blanket layer; and
etching the cladding material blanket layer over the redistribution layer (RDL).

15. The method of claim 14, wherein the etching comprises an anisotropic etch, such that the cladding material blanket layer over the sidewall of a top via is retained.

16. The method of claim 14, wherein the etching comprises a wet etch or isotropic etch in an unmasked area of photolithographic patterns, such that the cladding material blanket layer over the sidewall of a top via is retained.

17. The method of claim 14, wherein the etching comprises an anisotropic directional etch in an unmasked area of photolithographic patterns, such that the cladding material blanket layer over the sidewall of a top via is retained.

18. The method of claim 14, wherein the deposition of the at least one of the conformal oxide and the metal liner comprises depositing a conformal oxide over the top surface of a top via and a redistribution layer (RDL), wherein the conformal oxide is in contact with the top via and the surface of a redistribution layer (RDL).

19. A method of forming a via cladding structure comprising:
depositing at least one of a conformal oxide and a metal liner over the top surface of a top via and a redistribution layer (RDL) to form a cladding material blanket layer;
depositing a dielectric over a cladding material blanket layer and a redistribution layer (RDL);
removing the dielectric and the cladding material blanket layer over the top surface of the top via to expose the top surface of the top via.

20. The method of claim 19, wherein removing the dielectric and the cladding material blanket layer over the top surface of the top via comprise the removing the dielectric by etch back, where a coverage of a sidewall of the top via by the cladding material blanket layer is more than 70%.
